(19) United States
(12) Patent Application Publication
(10) Pub. No.: US 2026/0164827 A1
(43) Pub. Date: Jun. 11, 2026

(54) LIGHT DETECTION DEVICE AND ELECTRONIC DEVICE

(71) Applicant: SONY SEMICONDUCTOR SOLUTIONS CORPORATION, KANAGAWA (JP)

(72) Inventor: KEIJI NISHIDA, KANAGAWA (JP)

(21) Appl. No.: 18/707,178

(22) PCT Filed: Oct. 13, 2022
(86) PCT No.: PCT/JP2022/038228

§ 371 Date: May 3, 2024

(30) Foreign Application Priority Data
Nov. 11, 2021 (JP) 2021-184300

(51) Int. Cl. H10F 39/00; H10F 39/18

(52) U.S. Cl. CPC H10F 39/807; H10F 39/182; H10F 39/811

(57) ABSTRACT

Provided is a technique for improving production yield. A light detection device includes: a semiconductor layer having a first surface and a second surface located at opposite sides from each other in a thickness direction; an isolation region provided in the semiconductor layer and extending in the thickness direction of the semiconductor layer; a photoelectric conversion region partitioned by the isolation region; a conductor provided in the isolation region and extending in the thickness direction of the semiconductor layer; an interconnect conductive pad formed wider than a width of the conductor and connected, on the first surface side of the semiconductor layer, to the conductor so as to overlap with the conductor in plan view; and a contact part connected to the interconnect conductive pad so as to overlap therewith in plan view.

### TECHNICAL FIELD

The present technique (a technique according to the present disclosure) relates to a light detection device and an electronic device, and relates particularly to a technique useful for applications in a light detection device having photoelectric conversion regions partitioned by an embedded isolation region and an electronic device provided therewith.

### BACKGROUND ART

Light detection devices, such as solid-state image capturing devices or rangefinding devices, include a semiconductor layer having a plurality of photoelectric conversion regions partitioned by an isolation region. PTL 1 discloses an embedded isolation region in which a conductor (a doped polysilicon film) is embedded in a trench part of the semiconductor layer over an insulating film as an isolation region that partitions the photoelectric conversion regions. A technique in which the pinning of the side walls of the isolation region is strengthened by applying a negative bias to the conductor in the isolation region has also been disclosed.

### CITATION LIST

### Patent Literature

[PTL 1]

JP 2018-148116A

### SUMMARY

### Technical Problem

Incidentally, as a method for applying a potential to the conductor in the isolation region, there is a method in which power supply wiring of a multilayer wiring layer (wiring layer stack) stacked on the semiconductor layer is electrically connected to the conductor in the isolation region by power supply contact electrodes, and the potential is applied to the conductor in the isolation region from the power supply wiring through the power supply contact electrodes. In this case, the power supply contact electrode is formed by forming a connection hole in an interlayer insulating film of the multilayer wiring layer and selectively embedding a conductive film in the connection hole. Therefore, if the mask used when forming the connection hole in the interlayer insulating film is misaligned, the conductor in the isolation region and the power supply contact electrode will be misaligned as well.

Recent years have seen a trend toward the miniaturization of photoelectric conversion regions and the isolation regions as light detection devices are made smaller. With the conventional method of directly connecting the power supply contact electrode to the conductor in the isolation region, if the conductor is made narrower due to the isolation region being miniaturized, it becomes more difficult to connect the power supply contact electrode to the conductor in the isolation region. This connection difficulty affects the production yield of the light detection device and may therefore lead to a decrease in the yield.

An object of the present technique is to provide a technique capable of improving the production yield.

### Solution to Problem

(1) A light detection device according to another aspect of the present technique includes:
   a semiconductor layer having a first surface and a second surface located at opposite sides from each other in a thickness direction;
   an isolation region provided in the semiconductor layer and extending in the thickness direction of the semiconductor layer;
   a photoelectric conversion region partitioned by the isolation region;
   a conductor provided in the isolation region and extending in the thickness direction of the semiconductor layer;
   an electrode pad formed wider than a width of the conductor and connected, on the first surface side of the semiconductor layer, to the conductor so as to overlap with the conductor in plan view; and
   a contact part connected to the interconnect conductive pad so as to overlap therewith in plan view.
(2) An electronic device according to another aspect of the present technique includes the above-described light detection device and an optical system that forms an image of image light from a subject on the above-described light detection device.

### BRIEF DESCRIPTION OF DRAWINGS

FIG. 1 is a plan layout view schematically illustrating an example of the configuration of a solid-state image capturing device according to a first embodiment of the present technique.

FIG. 2 is a block diagram schematically illustrating an example of the configuration of the solid-state image capturing device according to the first embodiment of the present technique.

FIG. 3 is an equivalent circuit diagram illustrating an example of the configuration of a pixel in the solid-state image capturing device according to the first embodiment of the present technique.

FIG. 4 is a plan view schematically illustrating a planar pattern of an isolation region and an arrangement pattern of pixel transistors in a pixel array part of the solid-state image capturing device according to the first embodiment of the present technique.

FIG. 5 is a plan view illustrating part of FIG. 4 in an enlarged manner.

FIG. 6 is a diagram illustrating a transversal cross-sectional pattern of the isolation region in a transversal cross-section orthogonal to a thickness direction of a semiconductor layer.

FIG. 7 is a longitudinal cross-sectional view schematically illustrating a longitudinal cross-sectional structure along a line a4-a4 in FIG. 4.

FIG. 8 is a plan layout view of primary elements, schematically illustrating an example of the configuration of the pixel array part, and peripheral parts thereof, of the solid-state image capturing device according to the first embodiment of the present technique.

FIG. 9 is a longitudinal cross-sectional view schematically illustrating a longitudinal cross-sectional structure along a line a8-a8 in FIG. 8.

FIG. 10 is a plan layout view of primary elements, schematically illustrating a first variation on the first embodiment.

FIG. 11 is a longitudinal cross-sectional view schematically illustrating the longitudinal cross-sectional structure along a line a10-a10 in FIG. 10.

FIG. 12 is a plan layout view of primary elements, schematically illustrating a second variation on the first embodiment.

FIG. 13 is a longitudinal cross-sectional view schematically illustrating the longitudinal cross-sectional structure along a line a12-a12 in FIG. 12.

FIG. 14 is a plan view schematically illustrating a planar pattern of an isolation region and an arrangement pattern of pixel transistors in a pixel array part of the solid-state image capturing device according to a second embodiment of the present technique.

FIG. 15 is a longitudinal cross-sectional view schematically illustrating the longitudinal cross-sectional structure along a line a14-a14 in FIG. 14.

FIG. 16 is a longitudinal cross-sectional view of primary elements, schematically illustrating an example of the configuration of the solid-state image capturing device according to a third embodiment of the present technique.

FIG. 17 is a plan view of primary elements, schematically illustrating an example of the configuration of the pixel array part of the solid-state image capturing device according to a fourth embodiment of the present technique.

FIG. 18A is a plan view illustrating a first pixel block included in the pixel array part of FIG. 17 in an enlarged manner.

FIG. 18B is a plan view illustrating a second pixel block included in the pixel array part of FIG. 17 in an enlarged manner.

FIG. 19 is a longitudinal cross-sectional view schematically illustrating the cross-sectional structure along a line a17-a17 in FIG. 17.

FIG. 20 is a longitudinal cross-sectional view schematically illustrating a variation on the fourth embodiment.

FIG. 21 is a diagram illustrating the overall configuration of an electronic device according to a fifth embodiment of the present technique.

### DESCRIPTION OF EMBODIMENTS

Embodiments of the present technique will be described below with reference to the drawings.

In the descriptions of the drawings referred to in the following, identical or similar parts will be given identical or similar reference signs. However, it should be noted that the drawings are schematic, and the relationships between thicknesses and planar dimensions, the ratios of thicknesses of layers, and the like are different from the actual ratios, thicknesses, and the like. Therefore, specific thicknesses and dimensions should be determined in light of the following descriptions.

In addition, it goes without saying that the drawings also include portions having dimensional relationships and ratios different from each other. Furthermore, the effects described in the present specification are merely exemplary and not intended to be limiting, and other effects may be provided as well.

The definition of “transparent” in the present specification is assumed to refer to a state in which the transmittance of the member being referred to is close to 100% with respect to the assumed wavelength band for which the light detection device receives light. For example, even if the material itself absorbs the assumed wavelength band, a member processed to an ultra-thin state and thus having a transmittance of close to 100% is considered transparent. For example, with a light detection device used in the near-infrared range, even a member having high absorption in the visible light range can be said to be transparent if the transmittance in the near-infrared range is close to 100%. Alternatively, even if there are some absorbed components or reflected components, as long the effect thereof it is within an acceptable range in light of the sensitivity specifications of the light detection device, the member can be considered transparent.

The following embodiments exemplify devices and methods for embodying the technical spirit of the present technique, and the configurations are not limited to those described below. In other words, the technical spirit of the present technique can be modified in various ways within the technical scope set forth in the claims.

In addition, it is to be understood that definitions of directions such as “up-down” in the following descriptions are merely definitions provided for the sake of brevity and are not intended to limit the technical spirit of the present technique. For example, it is obvious that when an object is observed after being rotated by 90 degrees, up-down is transformed into and interpreted as left-right, and when an object is observed after being rotated by 180 degrees, up-down is interpreted as being inverted.

The following embodiments describe a case where as the conductivity types of semiconductors, a first conductivity type is p-type and a second conductivity type is n-type. However, the reverse relationship may be selected for the conductivity types, such that the first conductivity type is n-type and the second conductivity type is p-type.

Furthermore, in the following embodiments, in the three directions orthogonal to each other in a space, a first direction and a second direction orthogonal to each other in the same plane are defined as an X direction and a Y direction, respectively, and a third direction orthogonal to both the first direction and the second direction is defined as a Z direction. Finally, in the following embodiments, a thickness direction of a semiconductor layer 20 (described later) will be defined as being the Z direction.

### First Embodiment

The first embodiment will describe an example in which the present technique is applied to a solid-state image capturing device that is a backside-illuminated complementary metal oxide semiconductor (CMOS) image sensor, serving as a light detection device.

### Overall Configuration of Solid-State Image Capturing Device

The overall configuration of a solid-state image capturing device 1A will be described first.

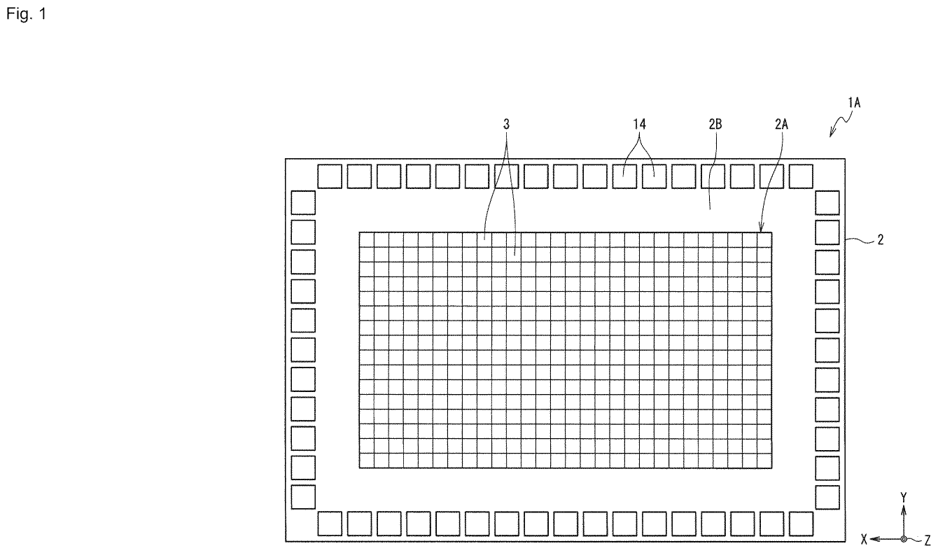

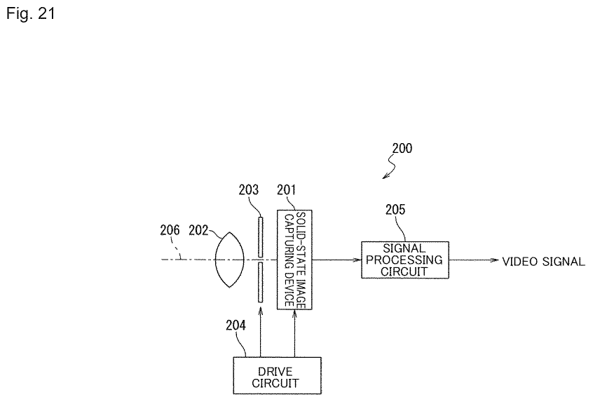

As illustrated in FIG. 1, the solid-state image capturing device 1A according to the first embodiment of the present technique is constituted mainly by a semiconductor chip 2, which has a square two-dimensional planar shape when viewed in plan view. In other words, the solid-state image capturing device 1A is installed on the semiconductor chip 2, and the semiconductor chip 2 can be therefore regarded as the solid-state image capturing device 1A. As illustrated in FIG. 21, the solid-state image capturing device 1A (201) takes in image light from a subject (incident light 206) through an optical lens 202, converts the amount of incident light 206 formed on an image capturing plane into electrical signals on a pixel-by-pixel basis, and outputs the electrical signals as pixel signals.

As illustrated in FIG. 1, the semiconductor chip 2 on which the solid-state image capturing device 1A is installed includes a square pixel array part 2A provided in a central area and a peripheral part 2B provided outside the pixel array part 2A so as to surround the pixel array part 2A, in a two-dimensional plane including the X direction and the Y direction orthogonal to each other.

The pixel array part 2A is a light-receiving surface that receives the light focused by the optical lens (optical system) 202 illustrated in FIG. 21, for example. In the pixel array part 2A, a plurality of pixels 3 are arranged in a matrix in the two-dimensional plane including the X direction and the Y direction. In other words, the pixels 3 are arranged in a repeating manner in both the X direction and the Y direction, which are orthogonal to each other in the two-dimensional plane.

As illustrated in FIG. 1, a plurality of bonding pads 14 are disposed in the peripheral part 2B. Each of the plurality of bonding pads 14, for example, is disposed along one of the four sides of the two-dimensional plane of the semiconductor chip 2. Each of the plurality of bonding pads 14 serves as an input/output terminal used when the semiconductor chip 2 is electrically connected to an external device.

### Logic Circuit

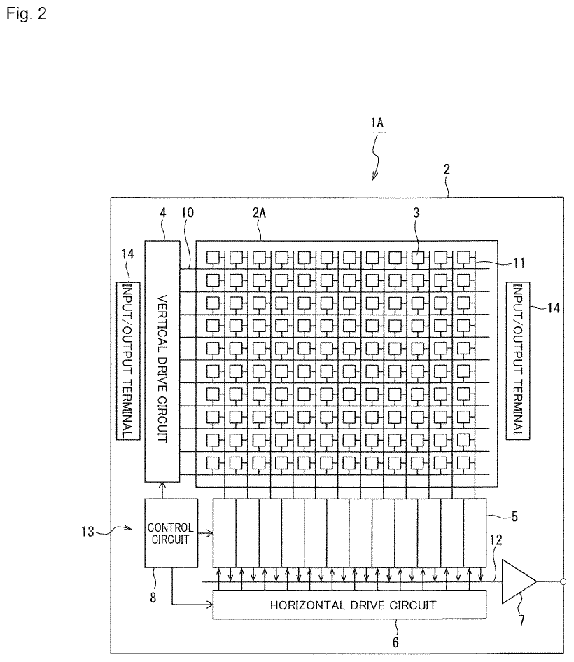

The semiconductor chip 2 includes a logic circuit 13, which is illustrated in FIG. 2. As illustrated in FIG. 2, the logic circuit 13 includes a vertical drive circuit 4, column signal processing circuits 5, a horizontal drive circuit 6, an output circuit 7, a control circuit 8, and the like. The logic circuit 13 is constituted by a Complementary MOS (CMOS) circuit having an n-channel conductive Metal Oxide Semiconductor Field Effect Transistor (MOSFET) and a p-channel conductive MOSFET as field effect transistors, for example.

The vertical drive circuit 4 is constituted by a shift register, for example. The vertical drive circuit 4 selects a desired pixel drive line 10 in sequence, supplies a pulse for driving the pixels 3 to the selected pixel drive line 10, and drives respective pixels 3 in units of rows. In other words, the vertical drive circuit 4 sequentially performs selective scanning of the pixels 3 of the pixel array part 2A in units of rows in a vertical direction, and supplies pixel signals from the pixels 3, which are based on signal charges generated in accordance with the amount of light received by the photoelectric conversion elements of the pixels 3, to the column signal processing circuits 5 through vertical signal lines 11.

The column signal processing circuits 5 are provided, for example, for corresponding columns of pixels 3, and perform signal processing such as noise removal for each pixel column on a signal output from the pixels 3 corresponding to one row. For example, the column signal processing circuit 5 performs signal processing such as correlated double sampling (CDS) and analog-digital (AD) conversion for removing pixel-specific fixed pattern noise.

The horizontal drive circuit 6 is constituted by a shift register, for example. The horizontal drive circuit 6 sequentially selects each column signal processing circuit 5 by sequentially outputting a horizontal scanning pulse to the column signal processing circuit 5, and outputs a pixel signal on which signal processing has been performed from each column signal processing circuit 5 to a horizontal signal line 12.

The output circuit 7 performs signal processing on the pixel signals sequentially supplied from the respective column signal processing circuits 5 through the horizontal signal line 12, and outputs the resulting pixel signals. Examples of the signal processing which may be used include buffering, black level adjustment, column variation correction, various types of digital signal processing, and the like, for example.

The control circuit 8 generates a clock signal or a control signal as a reference for operations of the vertical drive circuit 4, the column signal processing circuit 5, the horizontal drive circuit 6, and the like based on a vertical synchronization signal, a horizontal synchronization signal, and a master clock signal. In addition, the control circuit 8 outputs the generated clock signal or control signal to the vertical drive circuit 4, the column signal processing circuits 5, the horizontal drive circuit 6, and the like.

### Circuit Configuration of Pixel

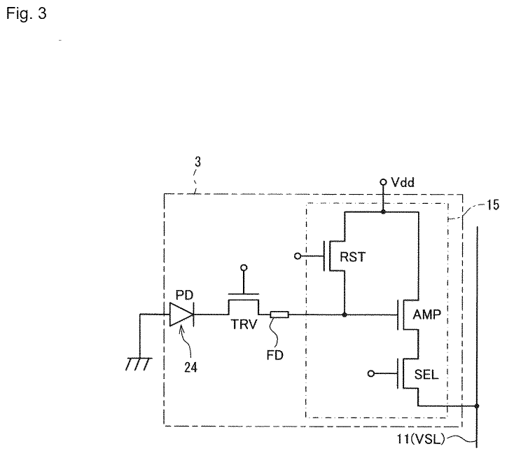

As illustrated in FIG. 3, each pixel 3 of the plurality of pixels 3 includes a photoelectric conversion unit 24, a transfer transistor TRV serving as a pixel transistor, and a charge holding region (floating diffusion) FD, and further includes a readout circuit 15 electrically connected to the charge holding region FD. Although the first embodiment will describe a circuit configuration in which one readout circuit 15 is assigned to one pixel 3 as an example, the configuration is not limited thereto, and a circuit configuration in which a single readout circuit 15 is shared by a plurality of pixels 3 may be used.

The photoelectric conversion unit 24 illustrated in FIG. 3 is constituted by, for example, a pn junction photodiode (PD), and generates a signal charge according to an amount of light received. The photoelectric conversion unit 24 is electrically connected to the source region of the transfer transistor TRL on the cathode side, and to a reference potential line (e.g., ground) on the anode side.

The transfer transistor TRV illustrated in FIG. 3 transfers a signal charge photoelectrically converted by the photoelectric conversion unit 24 to the charge holding region FD. The source region of the transfer transistor RTV is electrically connected to the cathode side of the photoelectric conversion unit 24, and the drain region of the transfer transistor TRV is electrically connected to the charge holding region FD. The gate electrode of the transfer transistor TRV is electrically connected to a transfer transistor drive line of the pixel drive line 10 (see FIG. 2).

The charge holding region FD illustrated in FIG. 3 temporarily holds (accumulates) the signal charge transferred from the photoelectric conversion unit 24 via the transfer transistor TRV.

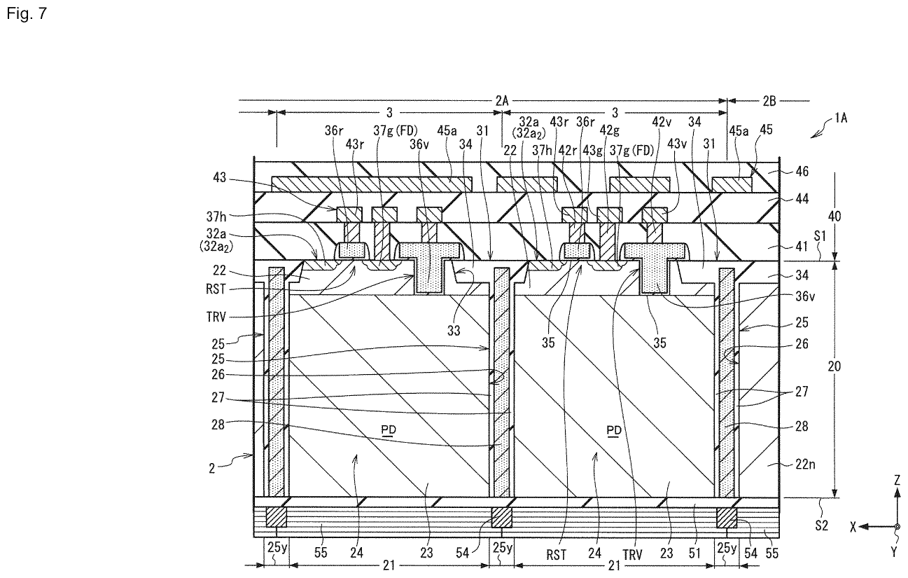

The photoelectric conversion unit 24, the transfer transistor TRV, and the charge holding region FD are provided in a photoelectric conversion region 21 (see FIG. 7) of the semiconductor layer 20 (described later).

The readout circuit 15 illustrated in FIG. 3 reads out the signal charge held in the charge holding region FD and outputs a pixel signal based on this signal charge. Although not limited thereto, the readout circuit 15 includes, for example, an amplifying transistor AMP, a selection transistor SEL, and a reset transistor RST as pixel transistors. Each of the transistors (AMP, SEL, RST) and the transfer transistor TRV described above is constituted by a MOSFET having, for example, a gate insulating film formed from a silicon oxide (SiO₂) film, a gate electrode, and a pair of main electrode regions functioning as a source region and a drain region, as a field effect transistor. The transistor may be a metal insulator semiconductor FET (MISFET) whose gate insulating film is a silicon nitride (a Si₃N₄) film or a layered film including a silicon nitride film, a silicon oxide film, or the like.

As illustrated in FIG. 3, the amplifying transistor AMP has a source region electrically connected to a drain region of the selection transistor SEL, and a drain region electrically connected to a power source line Vdd and a drain region of the reset transistor RST. The gate electrode of the amplifying transistor AMP is electrically connected to the charge holding region FD and a source region of the reset transistor RST.

The selection transistor SEL has a source electrically connected to the vertical signal line 11 (VSL), and a drain region electrically connected to a source region of the amplifying transistor AMP. The gate electrode of the selection transistor SEL is electrically connected to a selection transistor drive line of the pixel drive line 10 (see FIG. 2).

The reset transistor RST has a source region electrically connected to the charge holding region FD and the gate electrode of the amplifying transistor AMP, and a drain region electrically connected to the power source line Vdd and the drain region of the amplifying transistor AMP. The gate electrode of the reset transistor RST is electrically connected to a reset transistor drive line of the pixel drive line 10 (see FIG. 2).

When the transfer transistor TRV is turned on, the transfer transistor TRV transfers the signal charge generated by the photoelectric conversion unit 24 to the charge holding region FD.

When the reset transistor RST is turned on, the reset transistor RST resets the potential of the charge holding region FD (the signal charge) to the potential of the power source line Vdd. The selection transistor SEL controls the timing at which the pixel signal is output from the readout circuit 15.

The amplifying transistor AMP generates, as the pixel signal, a signal at a voltage based on the level of the signal charge held in the charge holding region FD. The amplifying transistor AMP constitutes a source-follower amplifier, and outputs a pixel signal at a voltage based on the level of the signal charge generated by the photoelectric conversion unit 24. When the selection transistor SEL is turned on, the amplifying transistor AMP amplifies the potential of the charge holding region FD and outputs a voltage based on that potential to the column signal processing circuit 5 over the vertical signal line 11 (VSL).

During the operation of the solid-state image capturing device 1A according to the first embodiment, the signal charge generated by the photoelectric conversion unit 24 of the pixel 3 is held (accumulated) in the charge holding region FD via the transfer transistor TRV of the pixel 3. The signal charge held in the charge holding region FD is then read out by the readout circuit 15 and applied to the gate electrode of the amplifying transistor AMP of the readout circuit 15. A horizontal line selection control signal is provided from the vertical shift register to the gate electrode of the selection transistor SEL of the readout circuit 15. Then, when the selection control signal is set to high (H) level, the selection transistor SEL becomes conductive, and a current corresponding to the potential of the charge holding region FD, amplified by the amplifying transistor AMP, flows in the vertical signal line 11. Additionally, when a reset control signal applied to the gate electrode of the reset transistor RST of the readout circuit 15 is set to high (H) level, the reset transistor RST becomes conductive and resets the signal charge accumulated in the charge holding region FD.

Note that the selection transistor SEL may be omitted as necessary. When the selection transistor SEL is omitted, the source region of the amplifying transistor AMP is electrically connected to the vertical signal line 11 (VSL).

### Specific Configuration of Solid-State Image Capturing Device

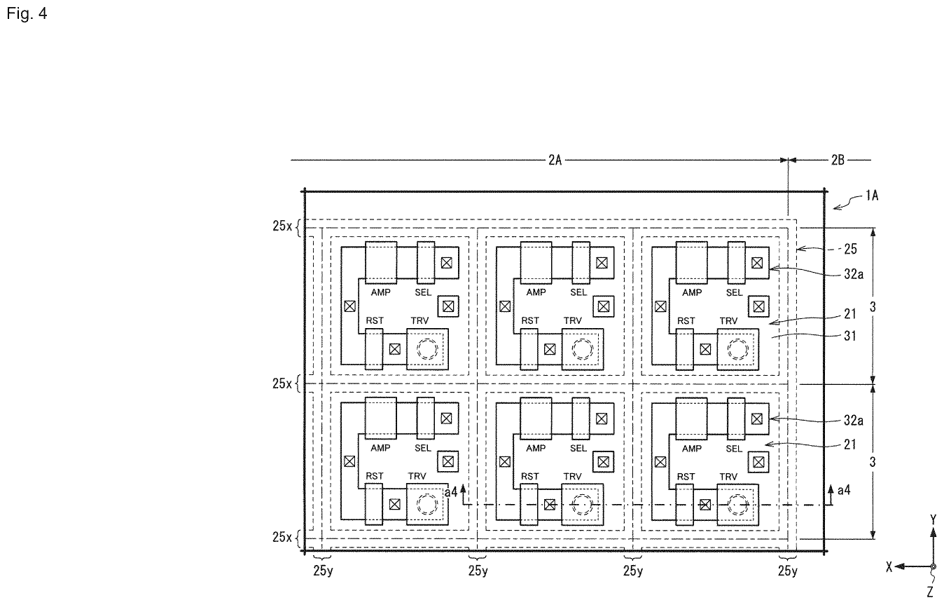

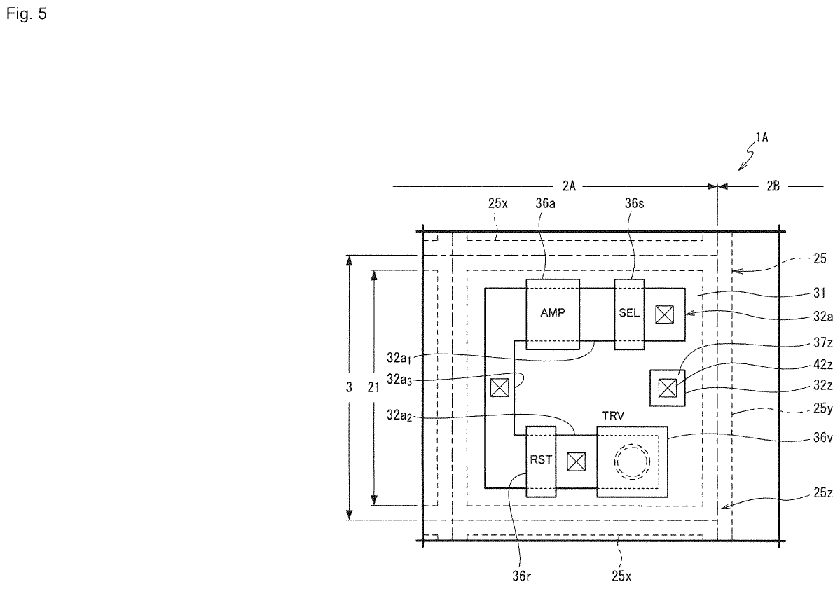

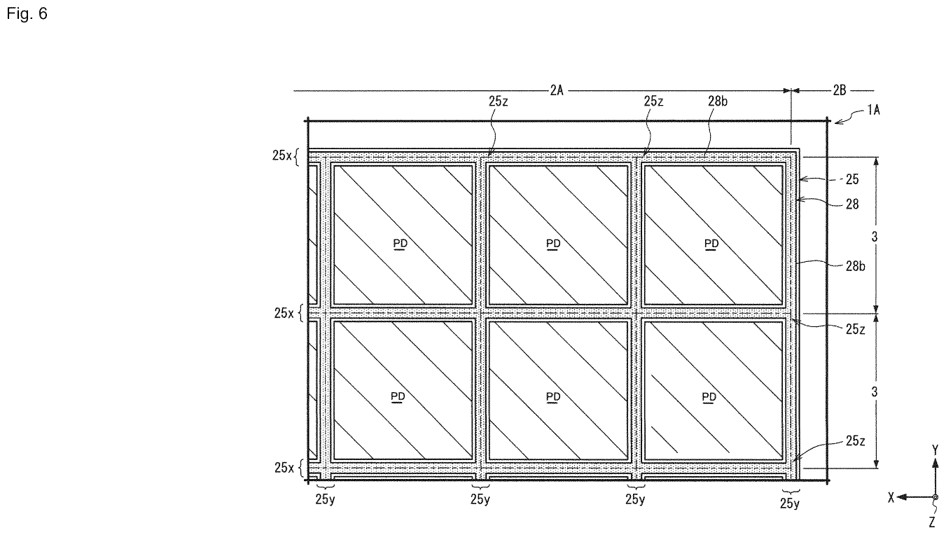

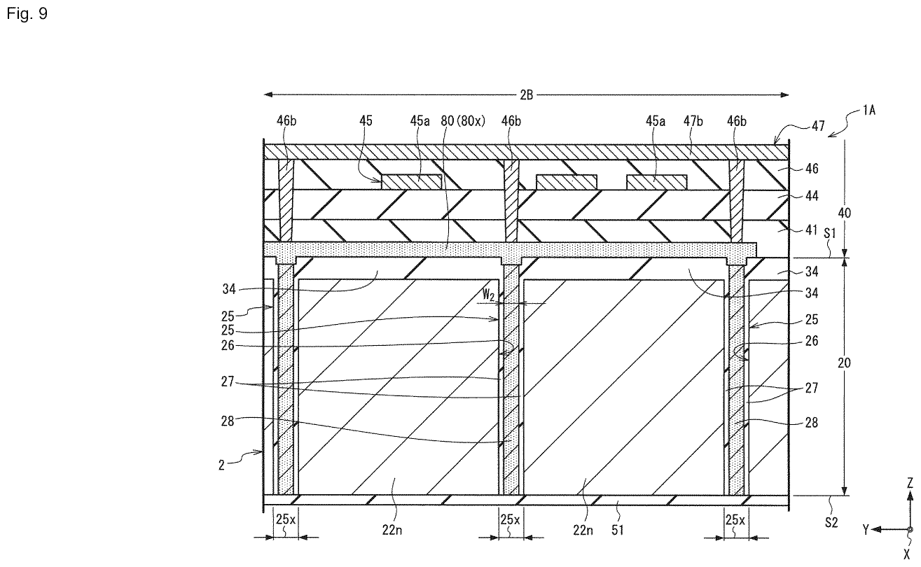

The specific configuration of the semiconductor chip 2 (the solid-state image capturing device 1A) will be described next with reference to FIGS. 4 to 9. Note that FIGS. 4 and 5 are plan views seen from a first surface S1 of the semiconductor layer 20 illustrated in FIG. 7. FIGS. 7 and 9 are flipped vertically relative to FIG. 1 to make the drawings easier to view. FIG. 7 also does not show layers higher than an interlayer insulating film 46 covering a wiring layer 45 in the second layer of a multilayer wiring layer (wiring layer stack) 40. FIG. 9 also does not show layers higher than a wiring layer 47 in the third layer of the multilayer wiring layer 40.

### Semiconductor Chip

As illustrated in FIG. 7, the semiconductor chip 2 includes the semiconductor layer 20, which has the first surface S1 and a second surface S2 located opposite from each other in the thickness direction (the Z direction); the multilayer wiring layer 40 provided on the first surface S1 side of the semiconductor layer 20; and a support substrate (not shown) provided on the opposite side of the semiconductor layer 20 from the multilayer wiring layer 40.

The semiconductor chip 2 also includes an insulating film 51, a light shielding film 54, a color filter 55, and a microlens (not shown) provided in that order, from the second surface S2 side, on the second surface S2 side of the semiconductor layer 20.

### Semiconductor Layer

As illustrated in FIGS. 4 to 7, the semiconductor layer 20 is provided with an isolation region 25 extending in the thickness direction of the semiconductor layer 20 (the Z direction), and a plurality of photoelectric conversion regions 21 partitioned by the isolation region 25. The photoelectric conversion regions 21 among the plurality of photoelectric conversion regions 21 are provided for corresponding ones of the pixels 3, and when viewed in plan view, are adjacent to each other with the isolation region 25 located therebetween. In other words, in the solid-state image capturing device 1A according to the first embodiment, the semiconductor layer 20 includes a plurality of photoelectric conversion regions 21 provided adjacent to each other with the isolation region 25, which extends in the thickness direction of the semiconductor layer 20 (the Z direction), located therebetween.

A device isolation region (field isolation region) 31, and an island-shaped device formation region (active region) 32a partitioned by the device isolation region 31, are provided on the first surface S1 side of the semiconductor layer 20. A power supply region 32z partitioned by the device isolation region 31 is also provided on the first surface S1 of the semiconductor layer 20. The device formation region 32a and the power supply region 32z are provided for each pixel 3. In other words, each pixel 3 among the plurality of pixels 3 disposed in the pixel array part 2A includes the photoelectric conversion region 21, the device formation region 32a, and the power supply region 32z.

A Si substrate, a SiGe substrate, an InGaAs substrate, or the like can be used as the semiconductor layer 20. In the first embodiment, a p-type semiconductor substrate constituted by single-crystal silicon, for example, is used as the semiconductor layer 20.

Here, the first surface S1 of the semiconductor layer 20 may also be referred to as a “device formation surface” or a “main surface”, and the second surface S2 side may be referred to as a “light incidence surface” or a “rear surface”. The solid-state image capturing device 1A according to the first embodiment uses the photoelectric conversion unit 24 provided in the photoelectric conversion region 21 of the semiconductor layer 20 to photoelectrically convert light incident from the second surface (light incidence surface, rear surface) S2 side of the semiconductor layer 20. “Plan view” refers to a view from a direction parallel to the thickness direction of the semiconductor layer 20 (the Z direction). “Cross-sectional view” refers to a cross-section parallel to the thickness direction of the semiconductor layer 20 (the Z direction) viewed from a direction orthogonal to the thickness direction of the semiconductor layer 20 (the Z direction) (that is, viewed from the X direction or the Y direction). The photoelectric conversion region 21 can also be referred to as a “photoelectric conversion cell”. The isolation region 25 can also be referred to as a “first isolation region”, and the device isolation region 31 as a “second isolation region”.

### Photoelectric Conversion Region

As illustrated in FIG. 7, in each of the plurality of photoelectric conversion regions (photoelectric conversion cells) 21, for example, a p-type well region 22 constituted by a p-type semiconductor region, and an n-type semiconductor region 23, are provided in that order from the first surface S1 side toward the second surface S2 side of the semiconductor layer 20. The p-type semiconductor region 22 is provided in a surface layer part on the first surface S1 side of the semiconductor layer 20, overlapping the n-type semiconductor region 23 in plan view. The n-type semiconductor region 23 is configured such that a top surface part on the first surface S1 side of the semiconductor layer 20 is separated from the first surface S1 of the semiconductor layer 20, a side surface part on the isolation region 25 side contacts a side wall of the isolation region 25, and furthermore, a bottom surface part on the second surface S2 side of the semiconductor layer 20 reaches the second surface S2 of the semiconductor layer 20. In other words, the photoelectric conversion region 21 is configured such that the top surface part of the n-type semiconductor region 23 is separated from the first surface S1 of the semiconductor layer 20, the side surface part of the n type semiconductor region 23 contacts a side wall of the isolation region 25, and furthermore, the bottom surface part of the n-type semiconductor region 23 reaches the second surface S2 of the semiconductor layer 20. The p-type well region 22 is provided overlapping the n-type semiconductor region 23 on the first surface S1 side of the semiconductor layer 20. Accordingly, when the photoelectric conversion regions 21 in the first embodiment have the same planar sizes, the volume of the photoelectric conversion unit 24 is greater than that of a photoelectric conversion region in which the p-type well region 22 is provided between the side surface part of the n-type semiconductor region 23 and the side wall of the isolation region 25.

Here, the photoelectric conversion unit 24 described above is mainly constituted by the n-type semiconductor region 23, and is configured as a pn junction photodiode (PD) by the p-type well region 22 and the n-type semiconductor region 23.

### Device Isolation Region

As illustrated in FIG. 7, although not limited thereto, the device isolation region 31 is configured having a shallow trench isolation (STI) structure in which an insulating film (field insulating film) 34 is selectively embedded in a groove 33 recessed from the first surface S1 side toward the second surface S2 side of the semiconductor layer 20. A silicon oxide film can be used as the insulating film 33, for example.

### Device Formation Region

As illustrated in FIGS. 5 and 7, the device formation region 32a is defined by the device isolation region 31 on the first surface S1 side of the semiconductor layer 20, and is provided for each photoelectric conversion region 21. The device formation region 32a overlaps the photoelectric conversion unit 24 of the electric conversion region 21 in plan view. The p-type well region 22 is provided in the device formation region 32a.

As illustrated in FIG. 5, the device formation region 32a is configured having a C-shaped planar pattern, having a first part 32a₁ and a second part 32a₂ each extending in the X direction and separated from each other in the Y direction, and a third part 32a₃ extending in the Y direction and connected to one end of each of the first part 32a₁ and the second part 32a₂. The amplifying transistor AMP and the selection transistor SEL are disposed in the first part 32a₁ so as to be connected in series. The reset transistor RST and the transfer transistor TRV are disposed in the second part 32a₂ so as to be connected in series. In the first embodiment, as illustrated in FIG. 4, the orientation of the planar pattern of the device formation region 32a is the same in each of the plurality of photoelectric conversion regions 21.

In other words, each of the plurality of photoelectric conversion regions 21 is provided with, for example, the above-described amplifying transistor AMP, selection transistor SEL, reset transistor RST, and transfer transistor TSV as pixel transistors. The pixel transistors (AMP, SEL, RST, and TSV) are provided in the p-type well region 22, which is provided on the first surface S1 side of the semiconductor layer 20 so as to overlap the photoelectric conversion unit 24 in plan view. In addition, the plurality of pixels 3, each including the photoelectric conversion region 21, the photoelectric conversion unit 24, and the pixel transistors, are arranged in a matrix (a two-dimensional matrix) in the pixel array part 2A. In the photoelectric conversion region 21, a signal charge corresponding to an amount of incident light is generated, and the generated signal charge is accumulated.

### Reset Transistor and Transfer Transistor

As illustrated in FIG. 7, the reset transistor RST is configured in the p-type well region 22 in the second part 32a₂ of the device formation region 32a. The reset transistor RST includes a gate insulating film 35 provided on the device formation region 32a on the first surface S1 side of the semiconductor layer 20, a gate electrode 36r provided on the device formation region 32a over the gate insulating film 35, and a side wall spacer provided in a side wall of the gate electrode 36r so as to surround the gate electrode 36r. The reset transistor RST further includes a channel formation region in which a channel (conduction path) is formed in the p-type well region 22 immediately below the gate electrode 36r, and a pair of main electrode regions 37g and 37h which are provided on respective sides of the channel formation region in the p-type well region 22 separated from each other in a channel longitudinal direction (a gate longitudinal direction) and which function as the source region and the drain region. The reset transistor RST controls a channel formed in the channel formation region using a gate voltage applied to the gate electrode 36r. In other words, the reset transistor RST is configured as a lateral type.

As illustrated in FIG. 7, the transfer transistor TRV is configured in the p-type well region 22 in the second part 32a₂ of the device formation region 32a. The transfer transistor TRV is configured as a vertical type. Specifically, the transfer transistor TRV includes a gate electrode 36v provided in a gate groove on the first surface S1 side of the semiconductor layer 20, the gate insulating film 35 interposed between the gate electrode 36v and the semiconductor layer 20, and a channel formation region constituted by the p-type well region 22 arranged in a side wall of the gate electrode 36v with the gate insulating film 35 interposed therebetween. The transfer transistor TRV also includes a pair of main electrode regions that function as the source region and the drain region. Of the pair of main electrode regions, one main electrode region is constituted by the n-type semiconductor region 23 (the photoelectric conversion unit 24), and the other main electrode region is constituted by the main electrode region 37g, which functions as the source region of the reset transistor RST. In other words, the transfer transistor TRV and the reset transistor RST share the main electrode region 37g that functions as the drain region of the transfer transistor TRV and the main electrode region 37g that functions as the source region of the reset transistor RST. The main electrode region 37g functions as the charge holding region FD illustrated in FIG. 3. The transfer transistor TRV controls a channel formed in the channel formation region using a gate voltage applied to the gate electrode 36v.

The gate electrode 36v includes a first part (a vertical gate electrode part) provided in the gate groove portion of the semiconductor layer 20 over the gate insulating film 35, and a second part formed integrally with the first part and protruding from the gate groove. The second part is wider than the first part.

Although not limited thereto, the main electrode region 37g includes an extension region constituted by an n-type semiconductor region and formed in self-alignment with the gate electrode 36r, an extension region constituted by an n-type semiconductor region and formed in self-alignment with the gate electrode 36v, and a contact region constituted by an n-type semiconductor region having a higher impurity concentration than the extension regions and formed in self-alignment with the side wall spacers of the respective side walls of the gate electrodes 36r and 36v.

Although not limited thereto, the main electrode region 37h includes an extension region constituted by an n-type semiconductor region and formed in self-alignment with the gate electrode 36r, and a contact region constituted by an n-type semiconductor region having a higher impurity concentration than the extension region and formed in self-alignment with the side wall spacer of the side wall of the gate electrode 36r.

Each of the gate insulating film 35 and the side wall spacer is constituted by a silicon oxide (SiO₂) film, for example. Each of the gate electrodes 36r and 36v is constituted by a silicon film (doped polysilicon film) containing impurities that reduce the resistance value, for example. Note that the transfer transistor TRV may be configured as a lateral type.

### Amplifying Transistor and Selection Transistor

As illustrated in FIG. 5, the amplifying transistor AMP and the selection transistor SEL are provided in the first part 32a₁ of the device formation region 32a. Although not illustrated in detail, the amplifying transistor AMP and the selection transistor SEL are configured in the p-type well region 22 described with reference to FIG. 7. Furthermore, although not illustrated in detail, each of the amplifying transistor AMP and the selection transistor SEL have almost the same configuration as that of the reset transistor RST described above. The amplifying transistor AMP and the selection transistor SEL share one main electrode region (source region) of the amplifying transistor AMP and the other main electrode region (drain region) of the selection transistor SEL.

Note that FIG. 7 illustrates the gate electrode 36r of the reset transistor RST and the gate electrode 36v of the transfer transistor TRV, respectively.

### Power Supply Region

A p-type power supply contact region 37z is provided in the power supply region 32z illustrated in FIG. 5. Although not illustrated in detail, to describe with reference to FIG. 7, the p-type power supply contact region 37z is provided in contact with the p-type well region 22 of the photoelectric conversion region 21, and is electrically connected to the p-type well region 22. The p-type power supply contact region 37z is electrically connected to power supply wiring formed in a wiring layer 43 in the first layer, over a power supply contact electrode 42z embedded in an interlayer insulating film 41. The p-type power supply contact region 37z is constituted by a p-type semiconductor region having a higher impurity concentration than the p-type well region 22, which reduces the ohmic contact resistance with the power supply contact electrode 42z connected to the p-type contact region 37z.

A first reference potential is applied to the p-type well region 22 illustrated in FIG. 7 as a power supply potential, and potentials are fixed to the first reference potential. The first reference potential is supplied to the p-type well region 22 from well power supply wiring provided in the multilayer wiring layer (described later), through the power supply contact electrode 42z and the power supply contact region 37z. Although not limited thereto, in the first embodiment, 0 V is applied to the p-type well region 22 as the first reference potential, for example. The application of the first reference potential to the p-type well region 22 is maintained during photoelectric conversion in the photoelectric conversion unit 24, during the driving of the pixel transistors (AMP, SEL, RST, and TRV), and the like.

### Multilayer Wiring Layer

As illustrated in FIGS. 7 and 9, the multilayer wiring layer 40 is disposed on the first surface S1 side of the semiconductor layer 20, which is the side opposite from the light incidence surface (second surface S2) side. Although not limited thereto, the multilayer wiring layer 40 has a stacked structure including interlayer insulating films 41, 44, and 46 and wiring layers 43, 45, and 47, for example.

As illustrated in FIG. 7, the interlayer insulating film 41 is provided in the pixel array part 2A on the first surface S1 side of the semiconductor layer 20 so as to cover the gate electrodes of the pixel transistors (AMP, SEL, RST, and STV). FIG. 7 illustrates a state in which the gate electrodes 36r and 36v of the reset transistor RST and the transfer transistor TRV, serving as the pixel transistors, are covered by the interlayer insulating film 41.

The wiring layer 43 in the first layer is provided on the interlayer insulating film 41, and the wiring layer 43 in the first layer is covered by the interlayer insulating film 44 in an upper layer. The wiring layer 45 in the second layer is provided on the interlayer insulating film 44, and the wiring layer 45 in the second layer is covered by the interlayer insulating film 46 in an upper layer. The wiring layer 47 in the third layer is provided on the interlayer insulating film 46. Although not illustrated, the wiring layer 47 in the third layer is covered by a protective film, for example, in an upper layer.

As illustrated in FIGS. 7 and 9, each of the interlayer insulating films 41, 44 and 46 is provided across the pixel array part 2A and the peripheral part 2B of the semiconductor chip 2.

Various wiring is formed in each of the wiring layers 43, 45, and 47 in the first to third layers. FIG. 7 illustrates wiring 43g, 43r, and 43v formed in the wiring layer 43 in the first layer, and wiring 45a formed in the wiring layer 45 in the second layer, respectively. FIG. 9 illustrates power supply wiring 47b formed in the wiring layer 47 in the third layer.

As illustrated in FIG. 7, the wiring 43g is electrically connected to one main electrode region 37g (FD) of the reset transistor RST via a contact electrode (conductive plug) 42g embedded in the interlayer insulating film 41. The wiring 43r is electrically connected to the gate electrode 36r of the reset transistor RST via a contact electrode 42r embedded in the interlayer insulating film 41. The wiring 43v is electrically connected to the gate electrode 36v of the transfer transistor TRV via a contact electrode (conductive plug) 42v embedded in the interlayer insulating film 41. The power supply wiring 47b illustrated in FIG. 9 will be described in detail later.

Each of the wiring layers 43, 45, and 47 in the first to third layers is constituted by a metal film such as copper (Cu) or an alloy mainly composed of Cu, for example. The interlayer insulating films 41, 44, and 46 and the protective film are constituted by, for example, a single layer of one of silicon oxide film, silicon nitride (Si₃N₄) film, or silicon carbonitride (SiCN) film, or a layered film in which two or more such films are layered. Each of the contact electrodes 42g, 42r, and 42v is constituted by a high-melting point metal film such as a tungsten (W) film or a titanium (Ti) film, for example.

The pixel transistors included in the readout circuit 15 are driven through the wiring in each of the wiring layers 43, 45, and 47. Additionally, because the multilayer wiring layer 40 is disposed on the side opposite from the side of the semiconductor layer 20 on which the light incidence surface side (the second surface S2 side) is located, the layout of the wiring can be set with freedom.

### Support Substrate

Although not illustrated in detail, the support substrate is provided on the side of the multilayer wiring layer 40 opposite from the side on which the semiconductor layer 20 is located. The support substrate is a substrate for ensuring the strength of the semiconductor layer 20 when the solid-state image capturing device 1A is manufactured. A silicon (Si) substrate, for example, can be used as the material of the support substrate.

### Isolation Region

As illustrated in FIGS. 4 and 5, the isolation region 25 includes a first part 25x extending in the X direction in plan view, and a second part 25y extending in the Y direction in plan view. The first part 25x and the second part 25y are orthogonal to each other.

The first part 25x is provided repeatedly at predetermined intervals in the Y direction. Likewise, the second part 25y is provided repeatedly at predetermined intervals in the X direction. In other words, in the isolation region 25, the planar pattern is a lattice-shaped planar pattern in plan view. Each of the plurality of photoelectric conversion regions 21 is partitioned by two second parts 25y of the isolation region 25 whose respective ends in the X direction are adjacent to each other, and by two first parts 25x of the isolation region 25 whose respective ends in the Y direction are adjacent to each other. The isolation region 25 having the lattice-shaped planar pattern has intersecting parts where the first parts 25x extending in the X direction and the second parts 25y extending in the Y direction intersect.

As illustrated in FIG. 7, each of the first part 25x and the second part 25y of the isolation region 25 extends in the thickness direction of the semiconductor layer 20 (the Z direction), and electrically and optically separates the photoelectric conversion regions 21 adjacent to each other in plan view. In the thickness direction of the semiconductor layer 20, for each of the first part 25x and the second part 25y, one end is connected to the device isolation region 31 and the other end reaches the second surface S2 of the semiconductor layer 20.

Each of the first part 25x and the second part 25y of the isolation region 25 includes an isolation insulating film 27 provided along an inner wall of a trench part 26 extending in the thickness direction of the semiconductor layer 20 (the Z direction), and a conductor 28 provided in the trench part 26 of the semiconductor layer 20 over the isolation insulating film 27. The conductor 28 is insulated from the semiconductor layer 20 by the isolation insulating film 27. In other words, the isolation region 25 includes the conductor 28 which is embedded in the semiconductor layer 20 over the isolation insulating film 27 and which is insulated from the semiconductor layer 20. The isolation insulating film 27 and the conductor 28 extend in the thickness direction of the semiconductor layer 20, with one end of each connected to the device isolation region 31 and the other end of each reaching the second surface S2 of the semiconductor layer 20.

A silicon oxide film can be used as the isolation insulating film 27, for example. A semiconductor film containing impurities that reduce the resistance value can be used as the conductor 28, for example. Although not limited thereto, the conductor 28 of the first embodiment is constituted by a p-type doped polysilicon film containing boron (B) as an impurity, for example. A metal film such as tungsten (W), aluminum (Al), copper (Cu), or an alloy film can also be used as the conductor 28.

Here, the trench part 26 includes a groove and through-holes formed by selectively removing parts of the semiconductor layer 20.

### Insulating Film and Light Shielding Film

As illustrated in FIG. 7, the insulating film 51 is provided on the second surface S2 side of the semiconductor layer 20. The insulating film 51 covers the entirety of the second surface S2 side of the semiconductor layer 20 in the pixel array part 2A such that the second surface S2 (light incidence surface) side of the semiconductor layer 20 is a flat, even surface. A silicon oxide film which transmits light is used as the insulating film 51, for example.

The light shielding film 54 is provided on the side of the insulating film 51 opposite from the side on which the semiconductor layer 20 is located. The light shielding film 54 has a lattice-shaped planar pattern which, viewed in plan view, forms openings to the light-receiving surfaces of the plurality of photoelectric conversion regions 21 having the planar pattern such that light incident on a predetermined photoelectric conversion region 21 does not leak into the adjacent photoelectric conversion regions 21. The light shielding film 54 is configured having the same lattice-shaped planar pattern as the lattice-shaped planar pattern of the isolation region 25, and is disposed in positions overlapping the isolation region 25 in plan view. A tungsten (W) film which blocks light is used as the light shielding film 54, for example.

### Color Filters and Microlenses

As illustrated in FIG. 7, the color filter 55 is provided for each photoelectric conversion region 21 (pixel 3) on the side of the insulating film 51 opposite from the side on which the semiconductor layer 20 is located (the light incidence surface side). The color filters 55 separate the colors of the light incident from the light incidence surface side of the semiconductor chip 2. A red (R) first color filter, a green (G) second color filter, and a blue (B) third color filter are provided as the color filters 55. In the first embodiment, three colors of color filters 55, namely R, G, and B, are provided.

Although not illustrated, to describe with reference to FIG. 7, the microlens is provided for each photoelectric conversion region 21 (pixel 3) on the side of the color filter 55 opposite from the side on which the semiconductor layer 20 is located (the light incidence surface side). The microlens 56 focuses irradiated light and efficiently causes the focused light to be incident on the photoelectric conversion region 21.

### Power Supply in Isolation Region

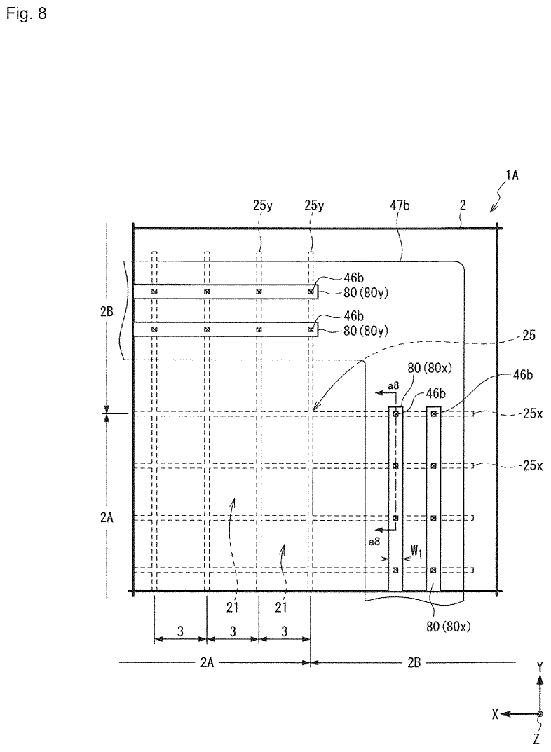

Next, a configuration will be described in which a power supply contact electrode 46b, serving as a contact part, is electrically and mechanically connected to the conductor 28 of the isolation region 25 through an interconnect conductive pad 80 in the peripheral part 2B outside the pixel array part 2A, as illustrated in FIGS. 8 and 9.

As illustrated in FIGS. 8 and 9, the solid-state image capturing device 1A according to the first embodiment includes the interconnect conductive pad 80, which is formed such that a width W₁ thereof (see FIG. 8) is greater than a width W₂ of the conductor 28 of the isolation region 25 (see FIG. 9) and which is connected so as to overlap with the conductor 28 of the isolation region 25 on the first surface S1 side of the semiconductor layer 20 when viewed in plan view, and the power supply contact electrode 46b, which serves as a power supply contact part connected so as to overlap with the interconnect conductive pad 80 when viewed in plan view. In the peripheral part 2B, the power supply wiring 47b at the power supply potential is electrically connected to the conductor 28 of the isolation region 25 via the interconnect conductive pad 80 and the power supply contact electrode 46b.

### Power Supply Wiring

As illustrated in FIG. 9, the power supply wiring 47b is formed in the wiring layer 47 in the third layer of the multilayer wiring layer 40. Furthermore, as illustrated in FIG. 8, the power supply wiring 47b is disposed in the peripheral part 2B outside the pixel array part 2A so as to surround the pixel array part 2A in plan view. The power supply wiring 47b is formed having an annular planar pattern, for example. Although not illustrated, the power supply wiring 47b is electrically connected to a power generation circuit that supplies a constant power supply potential, and the power supply potential is supplied from the power generation circuit. The supply of the power supply potential to the power supply wiring 45b is maintained during photoelectric conversion by the photoelectric conversion unit 24, during the driving of the readout circuit 15, and the like.

### Isolation Region

As illustrated in FIG. 8, the isolation region 25 is provided with the first parts 25x extending in the X direction being drawn from the pixel array part 2A into the peripheral part 2B so as to span the pixel array part 2A and the peripheral part 2B. Additionally, the isolation region 25 is provided with the second parts 25y extending in the Y direction being drawn from the pixel array part 2A into the peripheral part 2B so as to span the pixel array part 2A and the peripheral part 2B. Furthermore, as illustrated in FIGS. 8 and 9, each of the first part 25x and the second part 25y drawn into the peripheral part 2B overlaps the power supply wiring 47b in plan view. In other words, the isolation region 25 extends both inside and outside the pixel array part 2A.

### Interconnect Conductive Pad and Power Supply Contact Electrode

As illustrated in FIG. 8, in the first embodiment, a first interconnect conductive pad 80x overlapping with the first part 25x of the isolation region 25 in plan view and a second interconnect conductive pad 80y overlapping with the second part 25y of the isolation region 25 in plan view are provided as the interconnect conductive pad 80, for example, but the embodiment is not limited thereto. In other words, the interconnect conductive pad 80 of the first embodiment is divided into the first interconnect conductive pad 80x connected to the first part 25x of the isolation region 25 and the second interconnect conductive pad 80y connected to the second part 25y of the isolation region 25.

As illustrated in FIGS. 8 and 9, the first interconnect conductive pad 80x is disposed in the peripheral part 2B outside the pixel array part 2A, and extends in the Y direction. The first interconnect conductive pad 80x is electrically and mechanically connected to each of the plurality of first parts 25x of the isolation region 25 while overlapping therewith. Although FIG. 8 illustrates two first interconnect conductive pads 80x arranged in the X direction at predetermined intervals as an example, the number of first interconnect conductive pads 80x is not limited to two.

As illustrated in FIG. 8, the second interconnect conductive pad 80y is disposed in the peripheral part 2B outside the pixel array part 2A, and extends in the X direction. Although not illustrated in detail, the second interconnect conductive pad 80y is electrically and mechanically connected to each of the plurality of first parts 25x of the isolation region 25 while overlapping therewith. Although FIG. 8 illustrates two second interconnect conductive pads 80y arranged in the Y direction at predetermined intervals as an example, the number of second interconnect conductive pads 80y is not limited to two.

As illustrated in FIG. 9, the first interconnect conductive pad 80x is electrically connected to the power supply wiring 47b through the power supply contact electrode 46b serving as a contact part. Although not illustrated in detail, like the first interconnect conductive pad 80x, the second interconnect conductive pad 80y is electrically connected to the power supply wiring 47b through the power supply contact electrode 46b. In other words, in the peripheral part 2B outside the pixel array part 2A, the power supply wiring 47b is electrically connected to the conductor 28 of the isolation region 25 through the interconnect conductive pad 80 (80x and 80y) connected to the conductor 28 of the isolation region 25 (the conductor 28 of the first part 25x and the conductor 28 of the second part 25y) while overlapping therewith in plan view, and the power supply contact electrode 46b connected to the interconnect conductive pad 80 (80x and 8y) while overlapping therewith in plan view. A power supply potential is applied to the conductor 28 of the isolation region 25 from the power supply wiring 47b through the interconnect conductive pad 80 (80x and 80y) and the power supply contact electrode 46b, and the potential is fixed to the power supply potential.

The interconnect conductive pad 80 is interposed between the conductor 28 of the isolation region 25 and the power supply contact electrode 46b, and interconnects the electrical connection between the conductor 28 and the power supply contact electrode 46b. Although not limited thereto, the power supply contact electrode 46b is provided for each of the first part 25x and the second part 25y of the isolation region 25, for example.

As illustrated in FIG. 9, the power supply contact electrode 46b extends across the interlayer insulating films 46, 44 and 41 of the multilayer wiring layer 40, and is embedded across these interlayer insulating films 46, 44 and 41. The power supply contact electrode 46b is electrically and mechanically connected to the interconnect conductive pad 80 (80x and 80y) on one end, and the other end opposite from the one end is electrically and mechanically connected to the power supply wiring 47b. In other words, the power supply contact electrode 46b is electrically connected to the power supply wiring 47b which is provided in a higher layer than the power supply contact electrode 46b, and to which the potential is applied. The power supply contact electrode 46b is constituted by a high-melting point metal film such as a tungsten (W) film or a titanium (Ti) film, for example.

A second reference potential, which is a negative potential lower than the first reference potential applied to the p-type well region 22, is applied to the conductor 28 of the isolation region 25 illustrated in FIG. 9 as a power supply potential. For example, −1.2 V is applied as the second reference potential. The second reference potential to the conductor 28 of the isolation region 25 is supplied from the power supply wiring 47b through the power supply contact electrode 46b and the interconnect conductive pad 80 (80x and 80y), as illustrated in FIG. 9. In other words, different power supply potentials are applied to the p-type well region 22 of the photoelectric conversion region 21 (see FIG. 7) and the conductor 28 of the isolation region 25 that partitions the photoelectric conversion region 21. As illustrated in FIG. 9, a p-type peripheral well region 22n, constituted by a p-type semiconductor region, is provided in the semiconductor layer 20, in the peripheral part 2B of the semiconductor chip 2. The p-type peripheral well region 22n is formed in the same process as the p-type well region 22 provided in the semiconductor layer 20 in the pixel array part 2A of the semiconductor chip 2.

In the first embodiment, the isolation insulating film 27 of the isolation region 25 illustrated in FIG. 7 includes, for example, a Si-cover film (SCF) film that produces a negative fixed charge. Hafnium oxide (HfO₂) can be used for the SCF film. In this case, by applying the negative second reference potential to the conductor 28 of the isolation region 25, holes (h⁺) are induced in the side wall of the isolation region 25, which makes it possible to ensure pinning in the side wall of the isolation region 25 and control the occurrence of dark current.

### Main Effects of First Embodiment

The main effects of the first embodiment will be described next with comparison to a conventional technique. The conventional technique will be described with reference to the same reference numerals as those in the drawings of this embodiment.

There is a trend toward the miniaturization of the photoelectric conversion region 21 and the isolation region 25 as solid-state image capturing devices are made smaller. However, the power supply contact electrode 46b is formed by forming a connection hole that extends across the interlayer insulating films 46, 44 and 41 and then selectively embedding a conductive film in the connection hole. Therefore, if the mask used when forming the connection hole in the interlayer insulating film is misaligned, the conductor 28 in the isolation region 25 and the power supply contact electrode 46b will be misaligned as well.

Accordingly, with a method that directly connects the power supply contact electrode 46b to the conductor 28 of the isolation region 25, as in the conventional technique, if the conductor 28 is made narrower due to the miniaturization of the isolation region 25, it becomes more difficult to connect the power supply contact electrode 46 to the conductor 28 of the isolation region 25. This connection difficulty may lead to a decrease in the yield.

In contrast, in the first embodiment, the interconnect conductive pad 80, which is formed having a width W₁ greater than the width W₂ of the conductor 28 of the isolation region 25 and which is connected to the conductor 28 of the isolation region 25 while overlapping therewith in plan view, is provided as described above. The power supply contact electrode 46b is connected to the interconnect conductive pad 80. Accordingly, even if the conductor 28 is made narrower due to the miniaturization of the isolation region 25, the power supply contact electrode 46b can be connected to the interconnect conductive pad 80 with ease, which reduces the connection difficulty compared to when connecting the power supply contact electrode 46b to the conductor 28 of the isolation region 25 directly. Therefore, the solid-state image capturing device 1A according to the first embodiment makes it possible to improve the production yield.

Additionally, by applying the negative second reference potential to the conductor 28 of the isolation region 25, holes (h⁺) are induced in the side wall of the isolation region 25 adjacent to the photoelectric conversion region 21, which makes it possible to ensure pinning in the side wall of the isolation region 25 and control the occurrence of dark current.

Furthermore, because pinning can be ensured in the side wall of the isolation region 25, the n-type semiconductor region 23 can be provided so as to contact the side wall side of the isolation region 25 and reach the second surface S2 of the semiconductor layer 20. When the same planar size is used, the effective volume of the photoelectric conversion unit 24 can be increased compared with a photoelectric conversion region in which the p-type well region 22 is provided between the side surface part of the n-type semiconductor region 23 and the side wall of the isolation region 25. As a result, the solid-state image capturing device 1A according to the first embodiment can suppress a drop in a saturated signal quantity Qs caused by the miniaturization of the photoelectric conversion region 21.

Furthermore, the potential of the conductor 28 of the isolation region 25 can be fixed to the power supply potential, and thus in two photoelectric conversion regions 21 adjacent to each other with the isolation region 25 located therebetween, the propagation of noise caused by capacitive coupling of parasitic capacitance between the pixel transistors of one photoelectric conversion region 21 and the pixel transistors of another photoelectric conversion region 21 can be suppressed. Therefore, the solid-state image capturing device 1A according to the first embodiment makes it possible to improve the image quality. The reliability can be further improved as well.

Although a silicon film containing impurities that reduce the resistance value can be used as the conductor 8 of the isolation region 25, silicon film absorbs light, and it is therefore preferable to use a metal film such as aluminum (Al) from the standpoint of optics. In addition, the isolation region 25 does not necessarily need to penetrate the semiconductor layer 20, nor the semiconductor layer 20 in the conductor 28.

### Variations on First Embodiment

### First Variation

In the first embodiment described above, as illustrated in FIG. 9, the interconnect conductive pad 80 is disposed on the insulating film (field insulating film) 34 on the first surface S1 side of the semiconductor layer 20, and the interconnect conductive pad 80 is isolated from the semiconductor layer 20. However, the present technique is not limited to a configuration in which the interconnect conductive pad 80 is disposed on the insulating film 34.

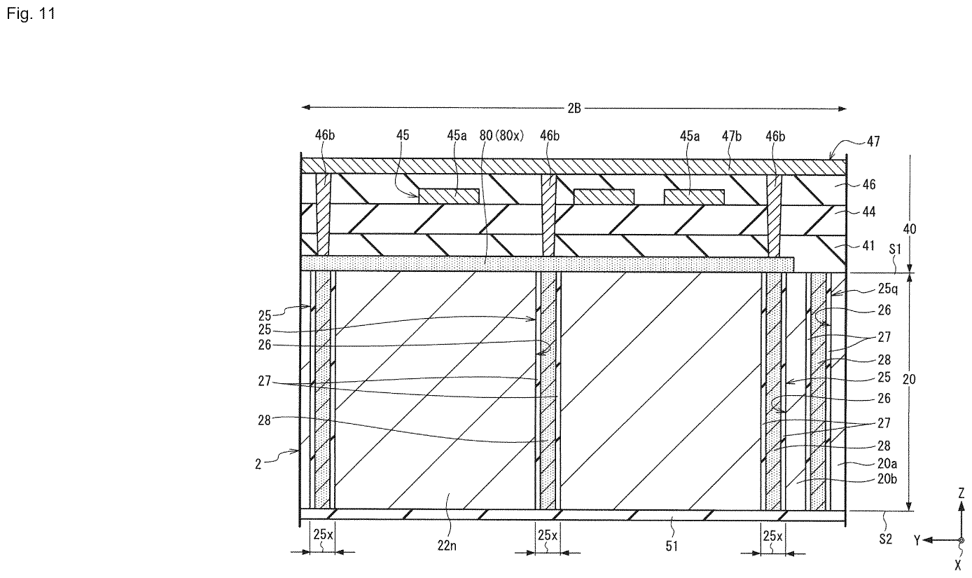

For example, as illustrated in FIG. 11, the interconnect conductive pad 80 may be made to contact the first surface S1 of the semiconductor layer 20.

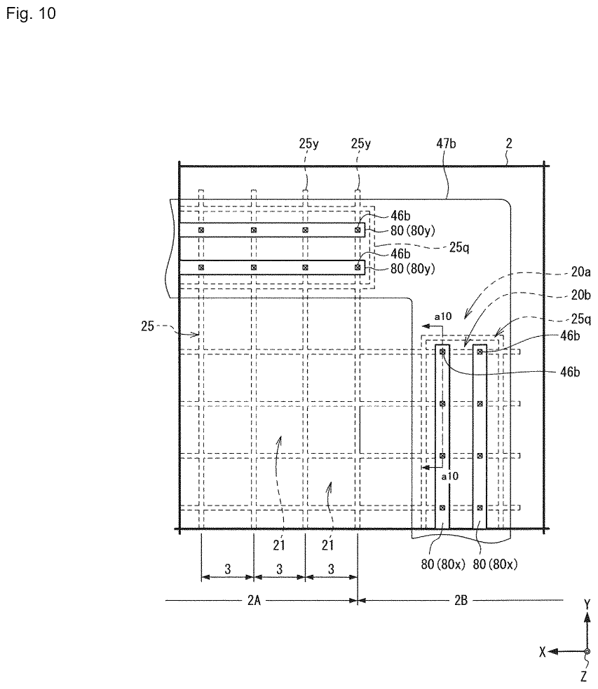

In this case, the semiconductor layer 20 in the peripheral part 2B and the interconnect conductive pad 80 are conductive. Therefore, as illustrated in FIGS. 10 and 11, a peripheral isolation region 25q surrounding the periphery of the interconnect conductive pad 80 when viewed in plan view is provided, a first region 20a outside the peripheral isolation region 25q and a second part 20b inside the peripheral isolation region 25q are partitioned, and the first region 20a and the second region 20b are electrically isolated from each other. By partitioning the semiconductor layer 20 in the peripheral part 2B into the first region 20a and the second region 20b using the peripheral isolation region 25q in this manner, different power supply potentials can be applied to the first region 20a outside the peripheral isolation region 25q and the second region 25b inside the peripheral isolation region 25 q. For example, the first reference potential (e.g., 0 V) can be applied to the first region 20a, and the negative second reference potential which is lower than the first reference potential (e.g., −1.2 V) can be applied to the second region 20b.

In this case, in the peripheral part 2B, the semiconductor layer 20 includes the first region 20a and the second region 20b, which are partitioned by the peripheral isolation region 25q and are electrically isolated from each other. The interconnect conductive pad 80 is connected to the conductor 28 of the isolation region 25 in the second region 20b of the semiconductor layer 20. The p-type peripheral well region 22n is provided in both the first region 20a and the second region 20b of the semiconductor layer 20. The peripheral isolation region 25q is formed in the same process as the isolation region 25, for example, and the longitudinal cross-sectional structure is the same as the longitudinal cross-sectional structure of the isolation region 25.

The first variation on the first embodiment provides similar effects to those of the first embodiment described above.

### Second Variation

The foregoing first embodiment described the interconnect conductive pad 80 (80x and 80y), which extends across a plurality of parts of the isolation region 25 (the first part 25x and the second part 25y) and which is electrically and mechanically connected to the plurality of parts (the first part 25x and the second part 25y) so as to overlap with each thereof. However, the present technique is not limited to the interconnect conductive pad 80 (80x and 80y) extending across the plurality of parts of the isolation region 25.

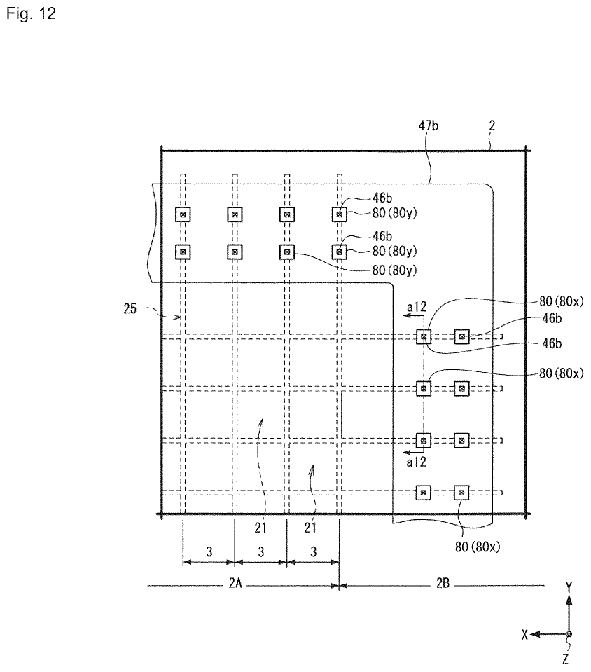

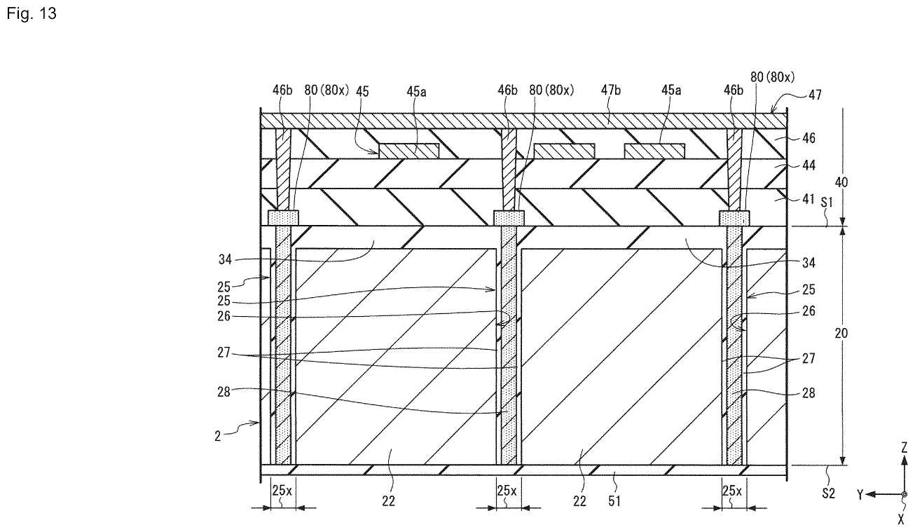

For example, as illustrated in FIGS. 12 and 13, the interconnect conductive pad 80 (80x and 80y) may be provided individually for each part of the isolation region 25 (the first part 25x and the second part 25y). The second variation on the first embodiment provides similar effects to those of the first embodiment described above.

### Third Variation

The foregoing first embodiment described a case where the interconnect conductive pad 80 is divided into the first interconnect conductive pad 80x connected to the conductor 28 at the first part 25x of the isolation region 25 and the second interconnect conductive pad 80y connected to the conductor 28 at the second part 25y of the isolation region 25. However, the one interconnect conductive pad 80 may be connected to each conductor 28 at the first part 25x and the second part 25y of the isolation region 25. In this case, the interconnect conductive pad 80 is preferably configured in an annular planar pattern surrounding the periphery of the pixel array part 2A.

### Second Embodiment

A solid-state image capturing device 1B according to a second embodiment of the present technique has basically the same configuration as the solid-state image capturing device 1A according to the first embodiment described above, with the exception of the following configurations.

In other words, the solid-state image capturing device 1A according to the first embodiment described above has a configuration in which the interconnect conductive pad 80 is electrically and mechanically connected to the conductor 28 of the isolation region 25 in the peripheral part 2B outside the pixel array part 2A, as illustrated in FIGS. 8 and 9.

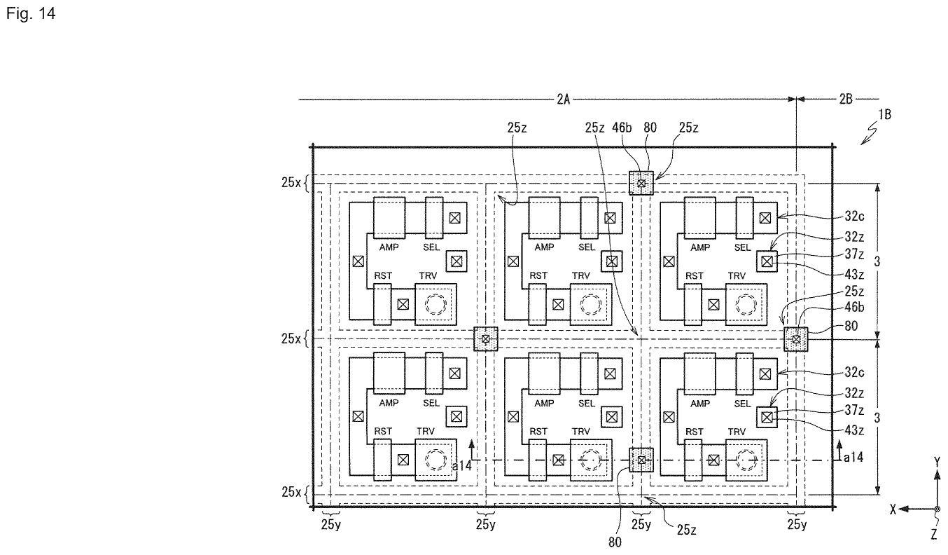

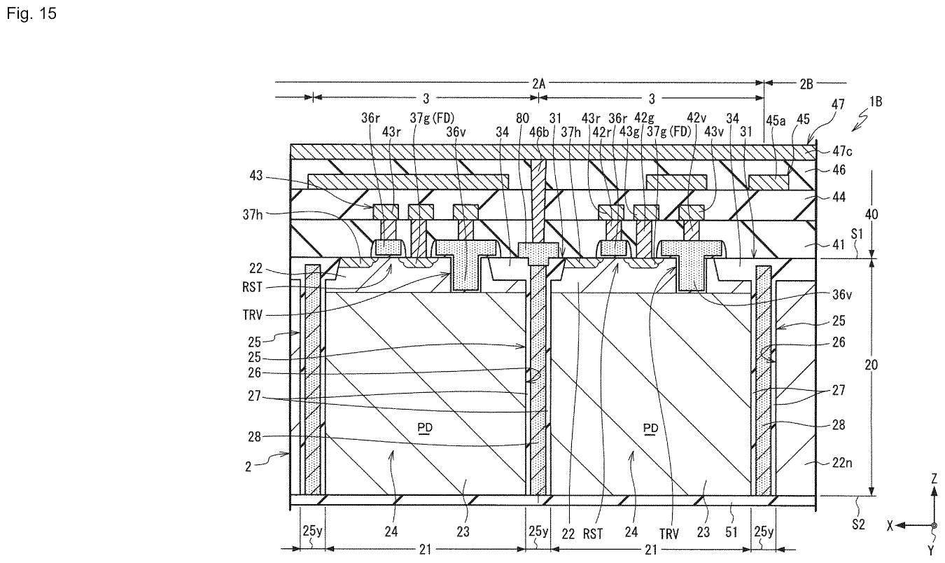

In contrast, as illustrated in FIGS. 14 and 15, the solid-state image capturing device 1B according to the second embodiment has an interconnect conductor pad 80 electrically and mechanically connected to the conductor 28 of the isolation region 25 in the pixel array part 2A. One end of the power supply contact electrode 46b is electrically and mechanically connected to the interconnect conductive pad 80, and power supply wiring 47c, which is integrated with the power supply wiring 47b, is electrically and mechanically connected to the other end of the power supply contact electrode 46b. The power supply wiring 47c is electrically connected to the conductor 28 of the isolation region 25 through the interconnect conductive pad 80 and the power supply contact electrode 46b. The interconnect conductive pad 80 is connected to the conductor 28 of the isolation region 25 located between the two photoelectric conversion regions 21 and 21 adjacent to each other.

In the second embodiment, as illustrated in FIGS. 14 and 15, the interconnect conductive pad 80 is provided in the isolation region 25 between two intersecting parts 25z and 25z where the first parts 25x of the isolation region 25 extending in the X direction and the second part 25y extending in the Y direction intersect, but the interconnect conductive pad 80 is preferably provided at the intersecting part 25z.

The solid-state image capturing device 1B according to the second embodiment provides effects similar to those of the solid-state image capturing device 1A according to the first embodiment described above.

### Third Embodiment

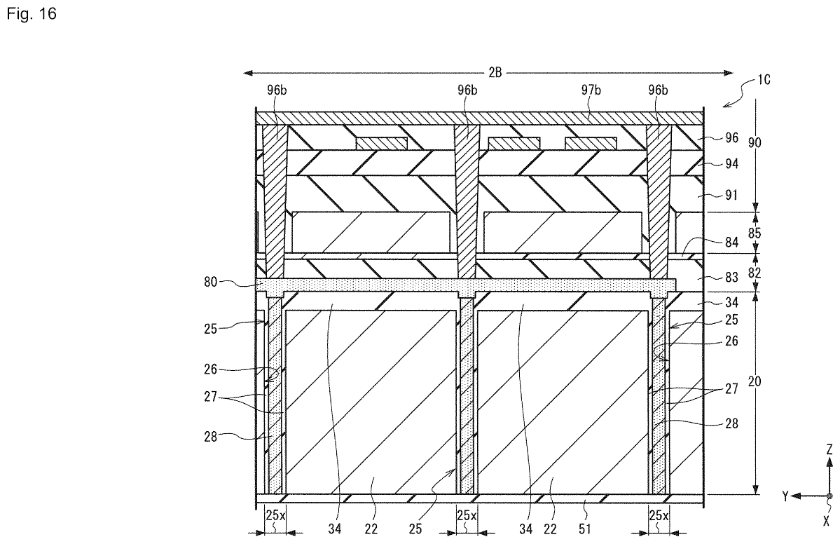

As illustrated in FIG. 16, a solid-state image capturing device 1C according to a third embodiment of the present technique has a dual-level structure in which two semiconductor layers 20 and 85 are stacked. FIG. 16 illustrates a longitudinal cross-sectional structure in the peripheral part 2B outside the pixel array part 2A, similar to FIG. 9 described above in the first embodiment. Specifically, the solid-state image capturing device 1C according to the third embodiment includes the semiconductor layer 20 as a first semiconductor layer, the semiconductor layer 85 as a second semiconductor layer provided on the first surface S1 side of the semiconductor layer 20 over an insulating layer 82, and a multilayer wiring layer 90 provided on the side of the semiconductor layer 85 opposite from the side on which semiconductor layer 20 is located.

The semiconductor layer 20 has a configuration similar to that of the semiconductor layer 20 of the first embodiment described above, and to describe with reference to FIGS. 9 and 7, includes the isolation region 25 and the photoelectric conversion regions 21 partitioned by the isolation region 25. As illustrated in FIGS. 9 and 16, the interconnect conductive pad 80 is provided on the first surface S1 side of the semiconductor layer 20 over the insulating film 34. As in the first embodiment described above, the interconnect conductive pad 80 is formed having a width W₁ greater than the width W₂ of the conductor 28 of the isolation region 25 and electrically and mechanically connected to the conductor 28 of the isolation region 25 while overlapping therewith in plan view.

Although not illustrated in detail in FIG. 16, in the third embodiment, the transfer transistor TRV is formed in the semiconductor layer 20, and the pixel transistors (AMP, SEL, and RST) included in the readout circuit are formed in the semiconductor layer 85.

As illustrated in FIG. 16, the insulating layer 82 includes an insulating film 83 covering the interconnect conductive pad 80 and an insulating film 84 provided on the side of the insulating film 83 opposite from the side on which the interconnect conductive pad 80 is located. The insulating film 83 corresponds to the interlayer insulating film 41 illustrated in FIGS. 9 and 7, and covers the transfer transistor TRV of the photoelectric conversion region 21 in the pixel array part 2A.

As illustrated in FIG. 16, the semiconductor layer 85 is provided on the side of the insulating layer 83 opposite from the side on which the semiconductor layer 20 is located. A p-type semiconductor substrate constituted by single-crystal silicon is used, for example, as the semiconductor layer 85, like the semiconductor layer 20. Although not limited thereto, the semiconductor layer 85 includes a through-hole through which a power supply contact electrode 96b, serving as a contact part, passes (described later).

As illustrated in FIG. 16, the multilayer wiring layer 90 includes an interlayer insulating film 91 covering the side of the semiconductor layer 85 opposite from the side on which the insulating layer 82 is located, an interlayer insulating film 94 provided on the side of the interlayer insulating film 91 opposite from the side on which the semiconductor layer 85 is located, an interlayer insulating film 96 provided on the side of the interlayer insulating film 94 opposite from the side on which the interlayer insulating film 91 is located, and a protective film (not shown) provided on the side of the interlayer insulating film 96 opposite from the side on which the interlayer insulating film 94 is located. The interlayer insulating films 91, 94, and 96 correspond to the interlayer insulating films 41, 44, and 46 illustrated in FIGS. 9 and 7.

Additionally, although not illustrated in detail, the multilayer wiring layer 90 includes a first layer wiring layer provided between the interlayer insulating film 91 and the interlayer insulating film 94, a second layer wiring layer provided between the interlayer insulating film 94 and the interlayer insulating film 96, and a third layer wiring layer provided between the interlayer insulating film 96 and the interlayer insulating film 94. The wiring layers correspond to the wiring layers 43, 45, and 47 illustrated in FIGS. 9 and 7.

Here, as illustrated in FIG. 16, the solid-state image capturing device 1C according to the third embodiment includes the power supply contact electrode 96b and power supply wiring 97b in place of the power supply contact electrode 46b and the power supply wiring 47b described above in the first embodiment with reference to FIG. 9.

The power supply wiring 97b is formed in the wiring layer in the third layer of the multilayer wiring layer 90, and a power supply potential is applied thereto. For example, the second reference potential is applied to the power supply wiring 97b as the power supply potential, in the same manner as in the first embodiment described above.

The power supply contact electrode 96b is electrically and mechanically connected to the interconnect conductive pad 80 on one end, and the other end opposite from the one end is electrically and mechanically connected to the power supply wiring 97b. The power supply contact electrode 96b passes through the through-hole in the semiconductor layer 85, and extends across the power supply wiring 97b and the interconnect conductive pad 80. The power supply contact electrode 96b is connected to the interconnect conductive pad 80 while overlapping when viewed in plan view.

The power supply potential is applied to the conductor 28 of the isolation region 25 from the power supply wiring 97b through the power supply contact electrode 96b and the interconnect conductive pad 80, and the potential is fixed to the power supply potential.

The solid-state image capturing device 1C according to the third embodiment provides effects similar to those of the solid-state image capturing device 1A according to the first embodiment described above.

The power supply contact electrode 96b of the third embodiment across the power supply wiring 97b provided in the multilayer wiring layer 90 in a layer higher than the semiconductor layer 85, and the interconnect conductive pad 80 provided in a layer lower than the semiconductor layer 85. This power supply contact electrode 46b is thicker (the area of the longitudinal cross-section is wider) than a normal power supply contact electrode that extends in the multilayer wiring layer 90, e.g., the power supply contact electrode 46b illustrated in FIG. 9. This increases the difficulty of the connection when the power supply contact electrode 96b is directly connected to the conductor 28 of the isolation region 25. It is therefore particularly useful to apply the present technique to the solid-state image capturing device 1C having such a power supply contact electrode 96b.

### Fourth Embodiment

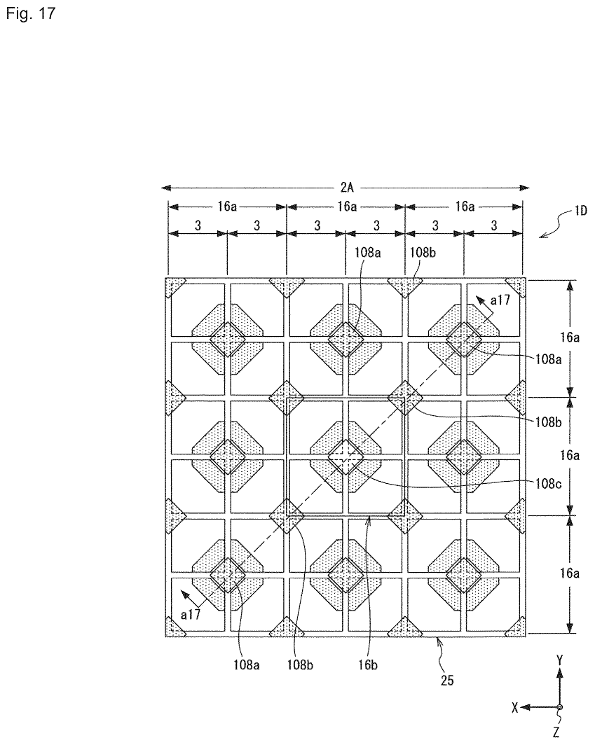

As illustrated in FIG. 17, a solid-state image capturing device 1D according to a fourth embodiment of the present technique includes a pixel array part 2B having first pixel blocks 16a and second pixel blocks 16b.

As illustrated in FIG. 17, the first pixel blocks 16a are arranged repeatedly in the X direction and the Y direction, which are orthogonal to each other in the two-dimensional plane. Each of the second pixel blocks 16b is provided at a point within a group of first pixel blocks in which the first pixel blocks 16a are arranged, and constitute a block column together with the first pixel blocks 16a. FIG. 17 illustrates, as an example, an arrangement pattern in which eight of the first pixel blocks 16a are arranged around one second block 16b. The second pixel blocks 16b may be arranged regularly or randomly.

Each of the first pixel blocks 16a and second blocks 16b includes, as a plurality of pixels 3 adjacent to each other, four of the pixels 3 arranged 2×2, with two each in the X direction and the Y direction, for example.

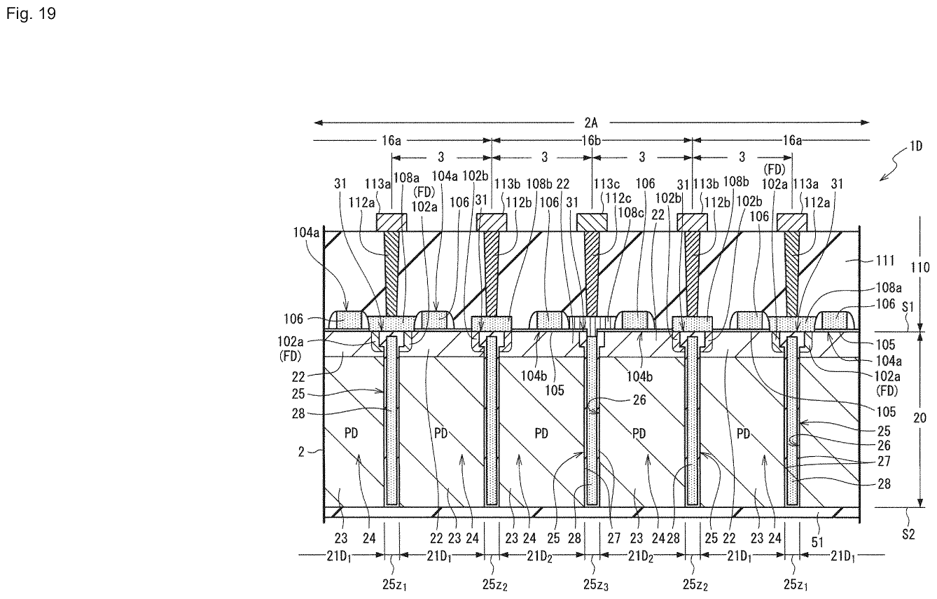

As illustrated in FIG. 19, the solid-state image capturing device 1D according to the fourth embodiment includes the semiconductor layer 20 having the first surface S1 and the second surface S2 located on opposite sides in the thickness direction (the Z direction), and a multilayer wiring layer 110 provided on the side of the semiconductor layer 20 on which the first surface S1 is located. Although not illustrated in detail in FIG. 19, like the first embodiment described above, the solid-state image capturing device 1D according to the fourth embodiment includes the insulating film 51, the light shielding film 54, the color filters 55, and the microlenses (on-chip lenses) provided on the second surface S2 side of the semiconductor layer 20, in that order from the second surface S2 side.

### Semiconductor Layer

As illustrated in FIG. 19, the semiconductor layer 20 includes the isolation region 25 extending in the thickness direction of the semiconductor layer 20 (the Z direction), photoelectric conversion regions 21D₁ and 21D₂ partitioned by the isolation region 25, and the device isolation region (field isolation region) 31 provided on the first surface S1 side of the semiconductor layer 20. The isolation region 25 is configured having a lattice-shaped planar pattern similar to the isolation region 25 of the first embodiment described above, and includes the first parts 25x extending in the X direction in plan view and the second parts 25y extending in the Y direction in plan view. The isolation region 25 is connected to the device isolation region 31 at one end, and reaches the second surface S2 of the semiconductor layer 20 on the end opposite from the one end. As in the first embodiment described above, the isolation region 25 includes the isolation insulating film 27 provided along the inner wall of the trench part 26 extending in the thickness direction of the semiconductor layer 20 (the Z direction), and the conductor 28 provided in the trench part 26 of the semiconductor layer 20 over the isolation insulating film 27.

### First Pixel Block

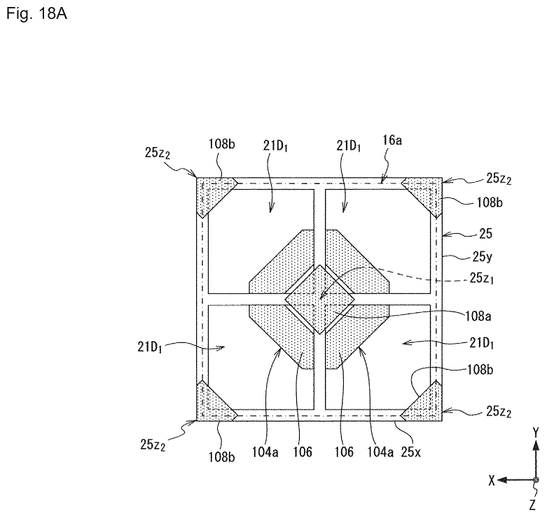

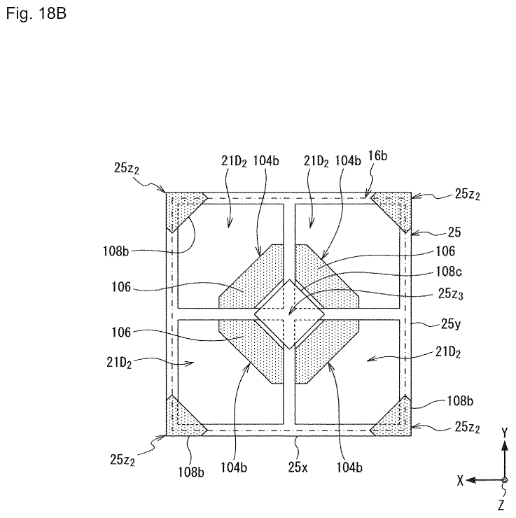

As illustrated in FIGS. 18A and 19, each of the four pixels 3 included in the first pixel block 16a includes the photoelectric conversion region 21D₁ provided in the semiconductor layer 20 and partitioned by the isolation region 25. In the first pixel block 16a, the four photoelectric conversion regions 21D₁ included in the first pixel block 16a are adjacent to each other with the isolation region 25 located therebetween when viewed in plan view. The first pixel block 16a includes a first intersecting part 25z₁ located in the center of the first pixel block 16a, i.e., in a central area surrounded by corners of the four photoelectric conversion regions 21D₁, and second intersecting parts 25z₂ at each of corners located on opposing corner lines from the corners of the four photoelectric conversion regions 21D₁ on the sides thereof where the first intersecting part 25z₁ is located, as intersecting parts where the first parts 25x and the second parts 25y of the isolation region 25 intersect.

As illustrated in FIG. 19, the photoelectric conversion region 21D₁ includes the n-type semiconductor region 23 provided in the semiconductor layer 20, and the p-type well region 22 provided overlapping the n-type semiconductor region 23 on the first surface S1 side of the semiconductor layer 20.

The photoelectric conversion region 21D₁ also includes an n-type contact region 102a provided, in a surface layer part of the p-type well region 22, adjacent to the first intersecting part 25z₁ of the isolation region 25 in plan view; a p-type contact region 102b provided, in the surface layer part of the p-type well region 22, adjacent to the second intersecting part 25z₂ of the isolation region 25 in plan view; and a transfer transistor 104a provided on the first surface S1 side of the semiconductor layer 20. The photoelectric conversion region 21D₁ also includes the photoelectric conversion unit 24.

The n-type contact region 102a is constituted by an n-type semiconductor region having a higher impurity concentration than the n-type semiconductor region 23, and functions as the charge holding region FD that holds (accumulates) the signal charge obtained from the photoelectric conversion by the photoelectric conversion unit 24. The p-type contact region 102b is constituted by a p-type semiconductor region having a higher impurity concentration than the p-type well region 22, and functions as a power supply contact region that supplies the power supply potential to the p-type well region 22.

As described above, the photoelectric conversion unit 24 is mainly constituted by the n-type semiconductor region 23, and is configured as a pn junction photodiode (PD) by the p-type well region 22 and the n-type semiconductor region 23.

The transfer transistor 104a includes a gate insulating film 105 provided on the first surface S1 of the semiconductor layer 20, a gate electrode 106 provided on the first surface S1 side of the semiconductor layer 20 over the gate insulating film 105, and a side wall spacer provided so as to surround the gate electrode 106 on the side wall of the gate electrode 106. The transfer transistor 104a also includes a channel formation region in which a channel (conduction path) is formed in the p-type well region 22 immediately below the gate electrode 106, the photoelectric conversion unit 24 (the n-type semiconductor region 23) that functions as the source region, and the charge accumulation region FD (the n-type contact region 102a) that functions as the drain region.

The transfer transistor 104a of each of the four photoelectric conversion regions 21D₁ included in the first pixel block 16a is disposed with the gate electrode 106 offset toward the first intersecting part 25z₁ side of the isolation region 25. Furthermore, the gate electrode 106 of each of the four transfer transistors 104a is disposed so as to surround the first intersecting part 25z₁.

### Second Pixel Block

As illustrated in FIGS. 18B and 19, each of the four pixels 3 included in the second pixel block 16b includes the photoelectric conversion region 21D₂ provided in the semiconductor layer 20 and partitioned by the isolation region 25.

In the second pixel block 16b, the four photoelectric conversion regions 21D₂ included in the second pixel block 16b are adjacent to each other with the isolation region 25 located therebetween when viewed in plan view. The second pixel block 16b includes a third intersecting part 25z₃ located in the center of the second pixel block 16b, i.e., in a central area surrounded by corners of the four photoelectric conversion regions 21D₂, and the second intersecting parts 25z₂ at each of corners located on opposing corner lines from the corners of the four photoelectric conversion regions 21D₂ on the sides thereof where the third intersecting part 25z₃ is located, as intersecting parts where the first parts 25x and the second parts 25y of the isolation region 25 intersect. The second intersecting part 25z₂ is shared by the first pixel block 16a and the second pixel block 16b. The second intersecting part 25z₂ is also shared by a plurality of the first pixel blocks 16a that are adjacent to each other.

As illustrated in FIG. 19, the photoelectric conversion region 21D₂ includes the n-type semiconductor region 23 provided in the semiconductor layer 20, and the p-type well region 22 provided overlapping the n-type semiconductor region 23 on the first surface S1 side of the semiconductor layer 20. The photoelectric conversion region 21D₂ also includes the p-type contact region 102b provided, in the surface layer part of the p-type well region 22, adjacent to the second intersecting part 25z₂ of the isolation region 25 in plan view, and a transfer transistor 104b provided on the first surface S1 side of the semiconductor layer 20. The photoelectric conversion region 21D₁ also includes the photoelectric conversion unit 24. Unlike the photoelectric conversion region 21D₁, the photoelectric conversion region 21D₂ does not include the n-type contact region 102a that functions as the charge holding region FD.

As described above, the photoelectric conversion unit 24 is mainly constituted by the n-type semiconductor region 23, and is configured as a pn junction photodiode (PD) by the p-type well region 22 and the n-type semiconductor region 23.

The transfer transistor 104b has basically the same configuration as the transfer transistor 104a described above, but does not include the charge accumulation region FD (the n-type contact region 102a) that functions as the drain region. In other words, the transfer transistor 104b does not transfer the signal charge obtained through the photoelectric conversion by the photoelectric conversion unit 24 to the charge holding region FD.

The transfer transistor 104b of each of the four photoelectric conversion regions 21D₂ included in the second pixel block 16b is disposed with the gate electrode 106 offset toward the third intersecting part 25z₃ side of the isolation region 25. Furthermore, the gate electrode 106 of each of the four transfer transistors 104b is disposed so as to surround the third intersecting part 25z₃.

### Conductive Pad and Interconnect Conductive Pad

As illustrated in FIGS. 18A and 19, a first conductive pad 108a is disposed at the first intersecting part 25z₁ of the isolation region 25. The first conductive pad 108a is provided overlapping the first intersecting part 25z₁ of the isolation region 25, and the four n-type contact regions 102a provided surrounding the first intersecting part 25z₁, in plan view, and is electrically and mechanically connected to each of the four n-type contact regions 102a. The first conductive pad 108a is disposed within a window part surrounded by the side wall spacer in the side wall of the gate electrode 106 of each of the four transfer transistors 104a, and is electrically isolated from the gate electrode 106 of each of the four transfer transistors 104a.

Additionally, as illustrated in FIGS. 18A and 19, a second conductive pad 108b is disposed at the second intersecting part 25z₂ of the isolation region 25. The second conductive pad 108 b is provided overlapping the second intersecting part 25z₂ of the isolation region 25, and the four p-type contact regions 102b provided surrounding the second intersecting part 25z₂, in plan view, and is electrically and mechanically connected to each of the four p-type contact regions 102b.

Additionally, as illustrated in FIGS. 18B and 19, an interconnect conductive pad 108c is disposed at the third intersecting part 25z₃ of the isolation region 25. The interconnect conductive pad 108c is provided overlapping the third intersecting part 25z₃ of the isolation region 25 in plan view, and is electrically and mechanically connected to the conductor 8 of the third intersecting part 25z₃. The interconnect conductive pad 108c is disposed within a window part surrounded by the side wall spacer in the side wall of the gate electrode 106 of each of the four transfer transistors 104b, and is electrically isolated from the gate electrode 106 of each of the four transfer transistors 104b.

Each of the interconnect conductive pads 108c and the first and second conductive pads 108a and 108b is formed, for example, in the same process. Each of the interconnect conductive pads 108c and the first and second conductive pads 108a and 108b is constituted by a silicon film containing impurities that reduce the resistance value, for example.

### Contact Electrode and Power Supply Contact Electrode

As illustrated in FIG. 19, the first conductive pad 108a is electrically connected to wiring 113a formed in the wiring layer of the multilayer wiring layer 110, over a contact electrode 112a provided in an interlayer insulating film 111 of the multilayer wiring layer 110. The contact electrode 112a extends in the thickness direction of the multilayer wiring layer 110 (the Z direction), and is electrically and mechanically connected at one end to the first conductive pad 108a, and is electrically and mechanically connected at another end opposite from the one end to the wiring 113a of the multilayer wiring layer 110. To describe with reference to FIG. 3 referred to in the first embodiment described above, the wiring 113a is electrically connected to the input side of the readout circuit 15.

As illustrated in FIG. 19, the second conductive pad 108b is electrically connected to wiring 113b formed in the wiring layer of the multilayer wiring layer 110, over a contact electrode 112b provided in the interlayer insulating film 111 of the multilayer wiring layer 110. The contact electrode 112b extends in the thickness direction of the multilayer wiring layer 110 (the Z direction), and is electrically and mechanically connected at one end to the second conductive pad 108b, and is electrically and mechanically connected at another end opposite from the one end to the wiring 113b. For example, the first reference potential of 0 V is applied to the wiring 113b as a power supply potential. In other words, the first reference potential is applied to the p-type well region 22 of each of the photoelectric conversion regions 21D₁ and 21D₂, and potentials are fixed to the first reference potential.

As illustrated in FIG. 19, the interconnect conductive pad 108c is electrically connected to power supply wiring 113c formed in the wiring layer of the multilayer wiring layer 110, over a power supply contact electrode 112c provided as a contact part in the interlayer insulating film 111 of the multilayer wiring layer 110. The power supply contact electrode 112c extends in the thickness direction of the multilayer wiring layer 110 (the Z direction), and is electrically and mechanically connected at one end to the interconnect conductive pad 108c, and is electrically and mechanically connected at another end opposite from the one end to wiring 113c. The second reference potential, which is a negative potential lower than the first reference potential applied to the p-type well region 22, is applied to the wiring 113c as a power supply potential. For example, −1.2 V is applied as the second reference potential. In other words, the second reference potential, which is a negative potential lower than the first reference potential applied to the p-type well region 22, is applied to the conductor 8 of the isolation region 25, and potential is fixed to the second reference potential.

### Main Effects of Fourth Embodiment

The solid-state image capturing device 1D according to the fourth embodiment provides effects similar to those of the solid-state image capturing device 1A according to the first embodiment described above.

Note that the photoelectric conversion region 21D₂ where the negative second reference potential is applied is a point defect, and it is therefore preferable to perform correction through signal processing. The interconnect conductive pad 108c may also be arranged regularly or randomly. The arrangement of the interconnect conductive pad 108c is not limited to the intersecting part of the isolation region 25, and the interconnect conductive pad 108c may be disposed between intersecting parts.

### Variation on Fourth Embodiment

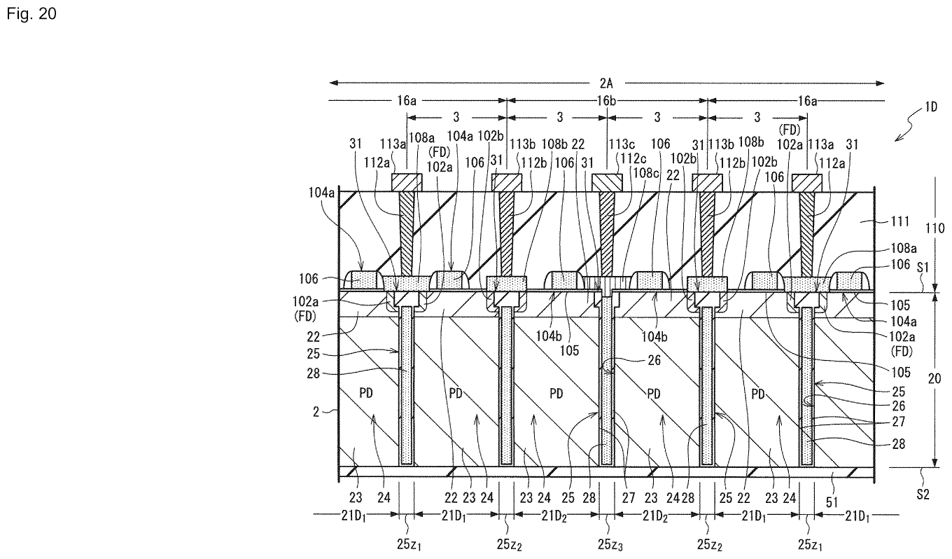

As illustrated in FIG. 20, the conductor 28 of the isolation region 25, aside from the part connected to the interconnect conductive pad 108c, may be such that the end on one side is generally flush with the bottom surface of the device isolation region 31 or lower than the bottom surface of the device isolation region 31. In other words, in the conductor 28 of the isolation region 25, the part connected to the interconnect pad 108c may selectively protrude more than other parts.

### Fifth Embodiment

### Example of Application in Electronic Device

The present technique (the technique according to the present disclosure) may be applied to various electronic devices, including image capturing devices such as digital still cameras and digital video cameras, mobile phones having image capturing functions, or other devices having image capturing functions, for example.

FIG. 21 is a diagram illustrating the overall configuration of an electronic device (e.g., a camera) according to a fifth embodiment of the present technique.

As illustrated in FIG. 21, an electronic device 200 includes a solid-state image capturing device 201, an optical lens 202, a shutter device 203, a driving circuit 204, and a signal processing circuit 205. This electronic device 200 indicates an embodiment in a case where the solid-state image capturing device (1A to 1D) according to the first to fourth embodiments of the present technique is used, as the solid-state image capturing device 201, in an electronic device (e.g., a camera).

The optical lens 202 forms an image of image light (incident light 206) from a subject on an image capturing plane of the solid-state image capturing device 201.

As a result, signal charges are accumulated in the solid-state image capturing device 201 over a set period. The shutter device 203 controls a light emission period and a light shielding period for the solid-state image capturing device 201. The driving circuit 204 supplies a drive signal for controlling a transfer operation of the solid-state image capturing device 201 and a shutter operation of the shutter device 203. An operation of transferring a signal to the solid-state image capturing device 201 is performed according to the drive signal (timing signal) supplied from the driving circuit 204. The signal processing circuit 205 performs various types of signal processing on signals (pixel signals) output from the solid-state image capturing device 201. A video signal having been subjected to the signal processing is stored in a storage medium such as a memory or output to a monitor.

According to this configuration, the electronic device 200 of the fifth embodiment controls the generation of dark current in the solid-state image capturing device 201, which makes it possible to improve the image quality.

The electronic device 200 to which the solid-state image capturing device of the foregoing embodiments can be applied is not limited to a camera, and the solid-state image capturing device can be applied to other electronic devices as well. For example, the solid-state image capturing device may be applied inn an image capturing device such as a camera module for a mobile device such as a mobile phone or a tablet terminal.

In addition to solid-state image capturing devices serving as image sensors as described above, the present technique can be applied in all types of light detection devices, including range sensors which measure distances, known as time of flight (ToF) sensors, and the like. A range sensor is a sensor that emits irradiated light toward an object, detects reflected light which returns when the irradiated light is reflected by a surface of the object, and calculates a distance to the object based on a time of flight from when the irradiated light is emitted to when the reflected light is received. The structure of the device isolation region described above can be employed as the structure of a device isolation region in the range sensor.

The present technique may be configured as follows.
(1) A light detection device including:
   a semiconductor layer having a first surface and a second surface located at opposite sides from each other in a thickness direction;
   an isolation region provided in the semiconductor layer and extending in the thickness direction of the semiconductor layer;
   a photoelectric conversion region partitioned by the isolation region;
   a conductor provided in the isolation region and extending in the thickness direction of the semiconductor layer;
   an interconnect conductive pad formed wider than a width of the conductor and connected, on the first surface side of the semiconductor layer, to the conductor so as to overlap with the conductor in plan view; and
   a contact part connected to the interconnect conductive pad so as to overlap therewith in plan view.
(2) The light detection device according to (1), further including:
   a pixel array part in which a plurality of pixels each including the photoelectric conversion region are arranged in a two-dimensional plane shape,
   wherein the isolation region extends both inside and outside the pixel array part in plan view, and
   the contact part is connected to the interconnect conductive pad at an outer side of the pixel array part.
(3) The light detection device according to (1) or (2),
   wherein in a peripheral part outside the pixel array part, the semiconductor layer includes a first region and a second region that are partitioned by a peripheral isolation region and are electrically isolated from each other, and
   the interconnect conductive pad is connected to both the conductor of the isolation region and the second region of the semiconductor layer.
(4) The light detection device according to (1) or (2), further including:
   a pixel array part in which a plurality of pixels each including the photoelectric conversion region are arranged in a two-dimensional plane shape,
   wherein the isolation region extends both inside and outside the pixel array part in plan view, and
   the contact part is connected to the interconnect conductive pad at an inner side of the pixel array part.
(5) The light detection device according to (4),
   wherein the interconnect conductive pad is connected to the conductor located between adjacent ones of a plurality of the photoelectric conversion regions.
(6) The light detection device according to any one of (1) to (5),
   wherein the contact part is electrically connected to wiring provided in a higher layer than the contact part and to which a potential is applied.
(7) The light detection device according to any one of (1) to (5),
   wherein the semiconductor layer is a first semiconductor layer, and the light detection device further including:
   a second semiconductor layer provided on the first surface side of the first semiconductor layer; and
   a multilayer wiring layer provided on a side of the second semiconductor layer opposite from a side on which the first semiconductor layer is located, and including the wiring,
   wherein one end of the contact part is connected to the interconnect conductive pad, and another end opposite from the one end is connected to the wiring.
(8) An electronic device including:
   the light detection device according to any one of (1) to (7);
   an optical lens that forms an image of image light from a subject on an image capturing plane of the light detection device; and
   a signal processing circuit that performs signal processing on a signal output from the light detection device.

The scope of the present technique is not limited to the exemplary embodiments illustrated in the drawings and described above, and includes all embodiments which have the object of the present technique and provide equivalent effects. Furthermore, the scope of the present technique is not limited to the combinations of features of the invention defined by the claims, and can be defined by all desired combinations of specific features among all the features disclosed.

### REFERENCE SIGNS LIST

1A, 1B, 1C, 1D Solid-state image capturing device
2 Semiconductor chip
2A Pixel array part
2B Peripheral part
3 Pixel
4 Vertical drive circuit
5 Column signal processing circuit
6 Horizontal drive circuit
7 Output circuit
8 Control circuit
10 Pixel drive line
11 Vertical signal line
13 Logic circuit
14 Bonding pad
15 Readout circuit
16a First pixel block
16b Second pixel block
20 Semiconductor layer
21, 21D₁, 21D₂ Photoelectric conversion region
22 p-type well region
23 n-type semiconductor region
24 Photoelectric conversion unit
25 Isolation region
25x First part
25y Second part
26 Trench part
27 Isolation insulating film
28 Conductor
31 Isolation region (inter-device isolation region)
32a Device formation region
32z Power supply region
33 Groove
34 Insulating film (embedded insulating film)
35 Gate insulating film
36r, 36v Gate electrode
37g, 37h Main electrode region
37z Power supply contact region
40 Multilayer wiring layer
41 Interlayer insulating film
42g, 42r, 42v Contact electrode
42z Power supply contact electrode
43 Wiring layer in first layer
43g, 43r, 43v Wiring
44 Interlayer insulating film
45 Wiring layer in second layer
45a Wiring
46 Interlayer insulating film
47 Wiring layer in third layer
47b Power supply wiring
51 Insulating film
54 Light shielding film
55 Color filter
80 Interconnect conductive pad
80x First interconnect conductive pad
80y Second interconnect conductive pad
82 Insulating layer
83 Insulating film
84 Insulating film
85 Semiconductor layer (second semiconductor layer)
90 Multilayer wiring layer
91, 94,96 Interlayer insulating film
96b Power supply contact electrode (contact part)
97b Power supply wiring
102a n-type first contact region (FD)
102b p-type second contact region
104a, 104b Transfer transistor
105 Gate insulating film
106 Gate electrode
108a First conductive pad
108b Second conductive pad
108c Interconnect conductive pad
110 Multilayer wiring layer
111 Interlayer insulating film
112a, 112b Contact electrode
112c Power supply contact electrode
113a, 113b Wiring
113c Power supply wiring

1. Alight detection device comprising:
a semiconductor layer having a first surface and a second surface located at opposite sides from each other in a thickness direction;
an isolation region provided in the semiconductor layer and extending in the thickness direction of the semiconductor layer;
a photoelectric conversion region partitioned by the isolation region;
a conductor provided in the isolation region and extending in the thickness direction of the semiconductor layer;
an interconnect conductive pad formed wider than a width of the conductor and connected, on the first surface side of the semiconductor layer, to the conductor so as to overlap with the conductor in plan view; and
a contact part connected to the interconnect conductive pad so as to overlap therewith in plan view.

2. The light detection device according to claim 1, further comprising:
a pixel array part in which a plurality of pixels each including the photoelectric conversion region are arranged in a two-dimensional plane shape,
wherein the isolation region extends both inside and outside the pixel array part in plan view, and
the contact part is connected to the interconnect conductive pad at an outer side of the pixel array part.

3. The light detection device according to claim 2,
wherein in a peripheral part outside the pixel array part, the semiconductor layer includes a first region and a second region that are partitioned by a peripheral isolation region and are electrically isolated from each other, and
the interconnect conductive pad is connected to both the conductor of the isolation region and the second region of the semiconductor layer.

4. The light detection device according to claim 1, further comprising:
a pixel array part in which a plurality of pixels each including the photoelectric conversion region are arranged in a two-dimensional plane shape,
wherein the isolation region extends both inside and outside the pixel array part in plan view, and
the contact part is connected to the interconnect conductive pad at an inner side of the pixel array part.

5. The light detection device according to claim 1,
wherein the interconnect conductive pad is connected to the conductor located between adjacent ones of a plurality of the photoelectric conversion regions.

6. The light detection device according to claim 1,
wherein the contact part is electrically connected to wiring provided in a higher layer than the contact part and to which a potential is applied.

7. The light detection device according to claim 1,
wherein the semiconductor layer is a first semiconductor layer, and the light detection device further comprising:
a second semiconductor layer provided on the first surface side of the first semiconductor layer; and
a multilayer wiring layer provided on a side of the second semiconductor layer opposite from a side on which the first semiconductor layer is located, and including the wiring,
wherein one end of the contact part is connected to the interconnect conductive pad, and another end opposite from the one end is connected to the wiring.

8. An electronic device comprising:
a light detection device;
an optical lens that forms an image of image light from a subject on an image capturing plane of the light detection device; and
a signal processing circuit that performs signal processing on a signal output from the light detection device,
wherein the light detection device includes:
a semiconductor layer having a first surface and a second surface located at opposite sides from each other in a thickness direction;
a plurality of photoelectric conversion regions provided adjacent to each other in the semiconductor layer with an isolation region extending in the thickness direction of the semiconductor layer;
a transistor provided on the first surface side of the semiconductor layer for each of the photoelectric conversion regions;
a conductor provided in the isolation region and extending in the thickness direction of the semiconductor layer; and
a transparent electrode provided on the second surface side of the semiconductor layer and electrically connected to the conductor on the second surface side of the semiconductor layer, a potential being supplied to the transparent electrode.
